(19) United States
(12) Patent Application Publication
(10) Pub. No.: US 2005/0170600 A1
(43) Pub. Date: Aug. 4, 2005

(54) Three-dimensional semiconductor package, and spacer chip used therein

(76) Inventor: Yukio Fukuzo, Kanagawa (JP)

Correspondence Address: YOUNG & THOMPSON, 745 SOUTH 23RD STREET, 2ND FLOOR, ARLINGTON, VA, 22202, US

(21) Appl. No.: 11/045,378

(22) Filed: Jan. 31, 2005

(30) Foreign Application Priority Data
Jan. 29, 2004 (JP) 2004-022310

(51) Int. Cl. H01L 21/20

(52) U.S. Cl. 438/396

(57) ABSTRACT

In a three-dimensional semiconductor package, a logic-circuit chip has a plurality of top electrode terminals formed on a top surface thereof, and a spacer chip is mounted on the logic-circuit chip. The spacer chip has a plurality of bottom electrode terminals formed on a bottom surface thereof, and a plurality of top electrode terminals formed on a top surface thereof and electrically connected to the respective bottom electrode terminals thereof. The mounting of the spacer chip on the logic-circuit chip is carried out such that the bottom electrode terminals of the spacer chip are bonded to the top electrode terminals of the logic-circuit chip, to thereby establish electrical connections therebetween. A memory chip is mounted on the spacer chip, and has a plurality of electrode terminals formed on a surface thereof. The mounting of the memory chip on the spacer chip is carried out such that the electrode terminals of the memory chip are bonded to the top electrode terminals of the spacer chip, to thereby establish electrical connections therebetween.

### BACKGROUND OF THE INVENTION

1. Field of the Invention

The present invention relates to a three-dimensional semiconductor package, so called a chip-on-chip (COC) type semiconductor package, containing a package board, and at least two large scale integrated (LSI) chips stacked one on top of another on the package board. Especially, the present invention may be advantageously and favorably applied to a specific-purpose or custom-made three-dimensional semiconductor package containing a large capacity memory chip.

2. Description of the Related Art

Conventionally, a large scale integrated (LSI) logic-circuit chip, such as a micro-processing unit chip or the like, and a large scale integrated (LSI) memory chip, such as a dynamic random access memory (DRAM) chip or the like, have been manufactured by individual production processes, and the logic-circuit chip and the memory chip are provided on a wiring board such that electrical connections are established between the logic-circuit chip and the memory chip. However, there is no technical reason why the logic-circuit chip and the memory chip should be manufactured by individual production processes. Thus, recently, a system-on-chip (SOC) type semiconductor package has been developed to meet the demands of higher performance, smaller and lighter size, and higher speed for various electronic tools, such as a mobile phone, a digital still camera (DSC), a digital video camera (DVC), a digital video disc (DVD), a desk top video (DTV), a multi-control unit (MCU) or the like. Namely, in the SOC type semiconductor package, both an LSI logic-circuit chip and an LSI memory chip are produced as one chip, resulting in achievement of the demands of higher performance, smaller and lighter size, and higher speed.

On the other hand, for progress and advance in LSI processing techniques, it is possible to produce a memory chip having a large capacity of 128 or 256 M bits and a plurality of pins on the order of several hundreds. Nevertheless, it is very difficult or impossible to increase the capacity of a memory to be produced in the chip of the SOC type semiconductor package, to 128 or 256 M bits, in that a yield rate of the SOC type semiconductor packages is considerably deteriorated when the memory having the large capacity (128 or 256 M bits) is incorporated in the chip of each of the SOC type semiconductor packages. Note, in general, it is said that the capacity of the memory, which can be incorporated in the chip of the SOC type semiconductor package, is not more than 128 M bits.

Under these circumstances, a system-in-package (SIP) type semiconductor package has been developed. In this SIP type semiconductor package, an LSI logic-circuit chip and an LSI memory chip, which are manufactured by individual production processes, are two-dimensionally or three-dimensionally provided on a package board having a wiring layout pattern formed thereon, and each of the logic-circuit chip and memory chip is electrically connected to the wiring layout pattern of the package board with a plurality of bonding wires, to thereby establish electrical connections between the logic-circuit chip and the memory chip. Thereafter, the logic-circuit chip and the memory chip are molded and sealed with a suitable resin material.

However, in the SIP type semiconductor package, it is impossible to obtain the same degree of performance as the SOC type semiconductor package, due to an increase of capacitance and resistance involved in the wiring layout pattern and the bonding wires. Note, in the SIP type semiconductor package, the capacitance may fall in a range from 20 pF to 50 pF.

Therefore, a chip-on-chip (COC) type three-dimensional semiconductor package has been developed, as disclosed in, for example, JP-A-H10-107202, JP-A-2000-260934 and JP-A-2002-334967. The COC three-dimensional type semiconductor package contains at least two chips stacked one on top of another.

For example, in JP-A-H10-107202, one of the two chips is produced as a face-down type LSI chip having a plurality of electrode pads formed a top surface thereof, and a plurality of metal bumps bonded to the electrode pads. The other LSI chip features a larger size than the face-down type LSI chip, and has a plurality of bonding pads formed along peripheral sides of a top surface thereof, and a plurality of electrode pads formed on a central area of the top surface encompassed by the peripheral bonding pads.

The face-down type LSI chip is faced down and mounted on the larger LSI chip such that the metal bumps of the face-down type LSI chip are bonded to the electrode pads of the larger LSI chip, resulting in production of a semiconductor module including the LSI chips stacked one on top of another.

After the production of the semiconductor module, it is associated with a lead frame, and each of the peripheral bonding pads of the larger LSI chip is electrically connected to a corresponding lead of the lead frame by a bonding wire, such as a gold wire or the like. Thereafter, the semiconductor module associated with the lead frame is sealed and molded with a suitable resin material, resulting in completion of the production of the COC type semiconductor package.

In this conventional COC type semiconductor package, since both the LSI chips are electrically and directly connected to each other through the intermediary of the small metal bumps, capacitance involved in the metal bumps becomes considerably smaller in comparison with the above-mentioned SIP type semiconductor package. Note, in general, in the COC type semiconductor package, the capacitance involved in the metal bumps is on the order of 1 pF. Thus, the COC type semiconductor package may feature as high operation speed as the above-mentioned SOC type semiconductor package.

Nevertheless, the aforesaid COC type semiconductor package is subjected to a limitation that the face-down type LSI chip must be smaller than the other LSI chip on which the face-down LSI chip is mounted, because the bonding-pads for the bonding wires must be prevented from being covered with the face-down type LSI chip.

### SUMMARY OF THE INVENTION

Therefore, a main object of the present invention is to provide a chip-on-chip type three-dimensional semiconductor package which can be constructed without being substantially subjected to a limitation of a size of a face-down type large scale integrated chip used therein.

Another object of the present invention is to provide a spacer chip incorporated in such a chip-on-chip type three-dimensional semiconductor package.

In accordance with a first aspect of the present invention, there is provided a three-dimensional semiconductor package, which comprises: a first semiconductor chip having a plurality of top electrode terminals formed on a top surface thereof; a spacer chip mounted on the first semiconductor chip and having a plurality of bottom electrode terminals formed on a bottom surface thereof, and a plurality of top electrode terminals formed on a top surface thereof and electrically connected to the respective bottom electrode terminals thereof, the mounting of the spacer chip on the first semiconductor chip being carried out such that the bottom electrode terminals of the spacer chip are bonded to the top electrode terminals of the first semiconductor chip, to thereby establish electrical connections therebetween; and a second semiconductor chip mounted on the spacer chip and having a plurality of electrode terminals formed on a surface thereof, the mounting of the second semiconductor chip on the spacer chip being carried out such that the electrode terminals of the second semiconductor chip are bonded to the top electrode terminals of the spacer chip, to thereby establish electrical connections therebetween.

The three-dimensional semiconductor package may further comprise a wiring board on which the first semiconductor chip is mounted. In this case, the first semiconductor chip may have a plurality of peripheral electrode terminals formed along a peripheral side of the surface thereof, and the mounting of the first semiconductor chip on the wiring board may be carried out such that the peripheral electrode terminals of the first semiconductor chip are electrically connected to the electrode terminals of the wiring board by electrical wires.

In the three-dimensional semiconductor package, a size of the second semiconductor chip may be larger than that of the spacer chip, and the mounting of the second semiconductor chip on the spacer chip is ensured without interfering with the electrical wires, due to the intervention of the spacer chip between the first semiconductor chip and the second semiconductor chip.

The three-dimensional semiconductor package may further comprise a molded resin enveloper encapsulating the first semiconductor chip, the spacer chip, and the second semiconductor chip together with the electrode terminals of the first and second semiconductor chips and the spacer chip.

The spacer chip may have a plurality of via plugs which are formed therein such that respective electrical connections are established between the bottom electrode and top electrode terminals formed on the bottom and top surface of the spacer chip.

The respective bottom electrode terminals of the spacer chip may be defined as bottom metal bumps bonded to bottom end faces of the via plugs. Also, the respective top electrode terminals of the spacer chip may be defined as top metal bumps bonded to top end faces of the via plugs.

The respective bottom electrode terminals of the spacer chip may be defined as bottom end faces of the via plugs. Also, the respective top electrode terminals of the spacer chip may be defined as top end faces of the via plugs.

The via plugs may be arranged such that bottom end faces of the via plugs have a mirror image relationship with respect to an arrangement of the top electrode terminals of the first semiconductor chip, and such that top end faces of the via plugs have a mirror image relationship with respect to an arrangement of the electrode terminals of the second semiconductor chip.

The spacer chip may have a bottom wiring layout pattern formed on the bottom surface thereof and electrically connected to the via plugs. In this case, the bottom electrode terminals of the spacer chip may be defined on the bottom wiring layout pattern such that there is a mirror image relationship between an arrangement of the bottom electrode terminals of the spacer chip and an arrangement of the electrode terminals of the first semiconductor chip. Optionally, a part of the bottom electrode terminals of the spacer chip may be defined on the bottom wiring layout pattern such that there is a mirror image relationship between an arrangement of the bottom electrode terminals of the spacer chip and an arrangement of the electrode terminals of the first semiconductor chip.

The spacer chip may have a top wiring layout pattern formed on the top surface thereof and electrically connected to the via plugs. In this case, the top electrode terminals of the spacer chip may be defined on the top wiring layout pattern such that there is a mirror image relationship between an arrangement of the top electrode terminals of the spacer chip and an arrangement of the electrode terminals of the second semiconductor chip. Optionally, a part of the top electrode terminals of the spacer chip may be defined on the top wiring layout pattern such that there is a mirror image relationship between an arrangement of the top electrode terminals of the spacer chip and an arrangement of the electrode terminals of the second semiconductor chip.

The three-dimensional semiconductor package may further comprise another semiconductor chip on which the first semiconductor chip is mounted. In this case, the first semiconductor chip has a plurality of bottom electrode terminals formed on a bottom surface thereof, and the other semiconductor chip has a plurality of top electrode terminals formed on a top surface thereof. The mounting of the first semiconductor chip on the other semiconductor chip is carried out such that the respective bottom electrode terminals of the first semiconductor chip are bonded to the top electrode terminals of the other semiconductor chip, to thereby establish electrical connections therebetween.

In accordance with a second aspect of the present invention, there is provided a spacer chip to be intervened between a first semiconductor chip and a second semiconductor chip to establish electrical connections therebetween. The spacer chip comprises a substrate having a plurality of bottom electrode terminals formed on a bottom surface thereof, and a plurality of top electrode terminals formed on a top surface thereof and electrically connected to the respective bottom electrode terminals thereof, and a plurality of via plugs formed in the substrate to establish respective electrical connections between the bottom electrode and top electrode terminals formed on the bottom and top surface of the substrate. The bottom electrode terminals of the spacer chip are arranged so as to have a mirror image relationship with respect to an arrangement of electrode terminals formed on the first semiconductor chip, and the top electrode terminals of the spacer chip are arranged so as to have a mirror image relationship with respect to an arrangement of electrode terminals formed on the second semiconductor chip.

The respective bottom electrode terminals of the substrate spacer chip may defined as bottom metal bumps bonded to bottom end faces of the via plugs, and the respective top electrode terminals of the substrate may be defined as top metal bumps bonded to top end faces of the via plugs. Also, the respective bottom electrode terminals of the substrate may be defined as bottom end faces of the via plugs, and the respective top electrode terminals of the substrate may be defined as top end faces of the via plugs.

The via plugs may be arranged such that bottom end faces of the via plugs have a mirror image relationship with respect to the arrangement of the electrode terminals of the first semiconductor chip, and such that top end faces of the via plugs have a mirror image relationship with respect to the arrangement of the electrode terminals of the second semiconductor chip.

The substrate may have a bottom wiring layout pattern formed on the bottom surface thereof and electrically connected to the via plugs. In this case, the bottom electrode terminals of the substrate may be defined on the bottom wiring layout pattern such that there is a mirror image relationship between the arrangement of the electrode terminals of the substrate and the arrangement of the electrode terminals of the first semiconductor chip. Optionally, a part of the bottom electrode terminals of the substrate may be defined on the bottom wiring layout pattern such that there is a mirror image relationship between an arrangement of the bottom electrode terminals of the substrate and the arrangement of the electrode terminals of the first semiconductor chip.

The substrate may have a top wiring layout pattern formed on the top surface thereof and electrically connected to the via plugs. In this case, the top electrode terminals of the substrate may be defined on the top wiring layout pattern such that there is a mirror image relationship between an arrangement of the top electrode terminals of the spacer chip and the arrangement of the electrode terminals of the second semiconductor chip. Optionally, a part of the top electrode terminals of the substrate may be defined on the top wiring layout pattern such that there is a mirror image relationship between the arrangement of the top electrode terminals of the spacer chip and the arrangement of the electrode terminals of the second semiconductor chip (178C).

Preferably, the substrate is composed of the same semiconductor material as the first and second semiconductor chips.

### BRIEF DESCRIPTION OF THE DRAWINGS

The above objects and other objects will be more clearly understood from the description set forth below, with reference to the accompanying drawings, wherein:

FIG. 1 is a partial cross-sectional view of a representative prior art chip-on-chip (COC) type three-dimensional semiconductor package structure;

FIG. 2 is a side view showing a semi-assembly of the prior art COC type three-dimensional semiconductor package, including a package board, and a large scale integrated (LSI) logic-circuit chip mounted thereon, together with a large scale integrated (LSI) memory chip which cannot be mounted on the logic-circuit chip due to the size of the memory chip being larger than that of the logic-circuit chip;

FIG. 3 is a partial cross-sectional view of a first embodiment of a COC type three-dimensional semiconductor package according to the present invention;

FIG. 4 is an exploded view of the first embodiment of the COC type semiconductor package shown in FIG. 3;

FIG. 5 is a partial cross-sectional view of a second embodiment of the COC type three-dimensional semiconductor package according to the present invention;

FIG. 6 is an exploded view of the second embodiment of the COC type semiconductor package shown in FIG. 5;

FIG. 7 is a plan view of an LSI logic-circuit chip used in the COC type three-dimensional semiconductor package shown in FIGS. 5 and 6;

FIG. 8 is a plan view of an LSI memory chip used in the COC type three-dimensional semiconductor package shown in FIGS. 5 and 6;

FIG. 9 is a top plan view of a spacer chip used in the COC type three-dimensional semiconductor package shown in FIGS. 5 and 6;

FIG. 10 is a bottom plan view of the spacer chip shown in FIG. 9;

FIG. 11 is a partial cross-sectional view of a modification of the third embodiment of the COC type three-dimensional semiconductor package according to the present invention;

FIG. 12 is a partial cross-sectional view of a third embodiment of the COC type three-dimensional semiconductor package according to the present invention;

FIG. 13 is a partial cross-sectional view of a fourth embodiment of the COC type three-dimensional semiconductor package according to the present invention;

FIG. 14 is a partially-enlarged view of FIG. 13;

FIG. 15 is a partial cross-sectional view of a fifth embodiment of the COC type three-dimensional semiconductor package according to the present invention;

FIG. 16 is a partially-enlarged view of FIG. 15;

FIG. 17 is a partial cross-sectional view of a sixth embodiment of the COC type three-dimensional semiconductor package according to the present invention;

FIG. 18 is a partially-enlarged view of FIG. 17;

FIG. 19A is a partial cross-sectional view of a silicon wafer, showing a first representative step of a first embodiment of a production method for producing a plurality of spacer chips according to the present invention;

FIG. 19B is a partial cross-sectional view, similar to FIG. 19A, showing a second representative step of the first embodiment of the production method according to the present invention;

FIG. 19C is a partial cross-sectional view, similar to FIG. 19B, showing a third representative step of the first embodiment of the production method according to the present invention;

FIG. 19D is a partial cross-sectional view, similar to FIG. 19C, showing a fourth representative step of the first embodiment of the production method according to the present invention;

FIG. 19E is a partial cross-sectional view, similar to FIG. 19D, showing a fifth representative step of the first embodiment of the production method according to the present invention;

FIG. 19F is a partial cross-sectional view, similar to FIG. 19E, showing a sixth representative step of the first embodiment of the production method according to the present invention;

FIG. 19G is a partial cross-sectional view, similar to FIG. 19F, showing a seventh representative step of the first embodiment of the production method according to the present invention;

FIG. 20A is a partial cross-sectional view, similar to FIG. 19D, showing a fifth representative step of a second embodiment of a production method for producing a plurality of spacer chips according to the present invention;

FIG. 20B is a partial cross-sectional view, similar to FIG. 20A, showing a sixth representative step of the second embodiment of the production method according to the present invention;

FIG. 20C is a partial cross-sectional view, similar to FIG. 20B, showing a seventh representative step of the second embodiment of the production method according to the present invention;

FIG. 21A is a partial cross-sectional view, similar to FIG. 20B, showing a seventh representative step of a third embodiment of a production method for producing a plurality of spacer chips according to the present invention;

FIG. 21B is a partial cross-sectional view, similar to FIG. 21A, showing an eighth representative step of the third embodiment of the production method according to the present invention;

FIG. 21C is a partial cross-sectional view, similar to FIG. 21B, showing a ninth representative step of the third embodiment of the production method according to the present invention; and

FIG. 21D is a partial cross-sectional view, similar to FIG. 21C, showing a tenth representative step of the third embodiment of the production method according to the present invention.

### DESCRIPTION OF THE PREFERRED EMBODIMENTS

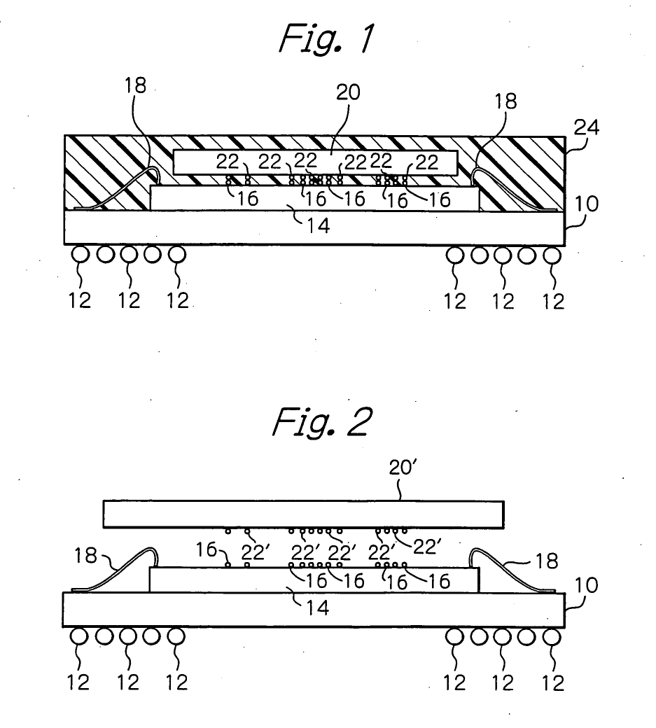

Before descriptions of embodiments of the present invention, for better understanding of the present invention, a representative prior art chip-on-chip (COC) type three-dimensional semiconductor package will be explained with reference to FIGS. 1 and 2.

The COC type three-dimensional semiconductor package includes a rectangular wiring-board 10, usually called an interposer or package board. The package board 10 has a plurality of via plugs (not visible) formed therethrough, and a plurality of solder balls 12, each of which is bonded to a bottom end face of a corresponding via plug, with an top end face of each via plug defining a terminal pad. Note, in FIGS. 1 and 2, the package board 10 is shown in a side view.

The COC type semiconductor package also includes a rectangular semiconductor chip or large scale integrated (LSI) logic-circuit chip 14, such as an application specific integrated circuit/micro-processing unit (ASIC/MPU) or the like, which is mounted on the package board 10. The logic-circuit chip 14 has a plurality of electrode pads (not shown) formed on a central area of a top surface thereof, and a plurality of bonding pads (not shown) formed along peripheral sides of the top surface thereof. The logic-circuit chip 14 is provided with a plurality of metal bumps 16 bonded to the electrode pads thereof. Also, the respective bonding pads of the logic-circuit chip 14 are electrically connected to the top faces of the via plugs of the package board 10 by bonding wires 18, using a wire bonding machine. Note, in FIGS. 1 and 2, the logic-circuit chip 14 is shown in a side view.

The COC type semiconductor package further includes another rectangular semiconductor chip or large scale integrated (LSI) memory chip 20, such as a dynamic random access memory chip having a large capacity of, for example, 128 M bits, which is mounted on the logic-circuit chip 14. In particular, the memory chip 20 is produced as a face-down (flip-chip) type memory chip, and has a plurality of electrode pads formed on a top surface thereof, with an arrangement of these electrode pads having a mirror image relationship with respect to an arrangement of the electrode pads of the logic-circuit chip 14. Also, the memory chip 20 is provided with a plurality of metal bumps 22 bonded to the electrode pads thereof. In FIG. 1, the memory chip 20 is shown in a side view.

Thus, by facing the memory chip 20 down, the mounting of the memory chip 20 is made possible such that the metal bumps 22 of the memory chip 20 are bonded to the metal bumps 16 of the logic-circuit chip 14 by using, for example, either an ultrasonic-pressure bonding process or a heat-pressure bonding process, to thereby establish electrical connections therebetween, as shown in FIG. 1.

After the mounting of the memory chip 20 is completed, the logic-circuit chip 14 and the memory chip 20 are sealed and molded with a suitable resin material, by using, for example, a transfer molding process, to thereby produce a molded resin enveloper 24 encapsulating the chips 14 and 20 together with the metal bumps 16 and 22. Thus, the production of the COC type semiconductor package as shown in FIG. 1 is completed. Note, in FIG. 1, the molded resin enveloper 24 is shown in a cross-sectional view.

This COC type semiconductor package features a higher operation speed, because the semiconductor chips 14 and 20 are electrically connected to each other through the intermediary of the small metal bumps 16 and 22, i.e. because capacitance and resistance involved in the metal bumps 16 and 22 are considerably small.

However, as shown in FIG. 2, an LSI memory chip 20′ having a large capacity of, for example, 256 M bits, cannot be mounted on the logic-circuit chip 14, because the large capacity memory chip 20′ has a larger size than that of the logic-circuit chip 14. Namely, when the large capacity memory chip 20′ is used, it is impossible to bond the respective bonding wires 18 to the bonding pads formed on the logic-circuit chip 14. Note, in FIG. 2, the large capacity memory chip 20′ is shown in a side view, and references 22′ indicate metal bumps bonded to electrode pads of the memory chip 20′

### First Embodiment

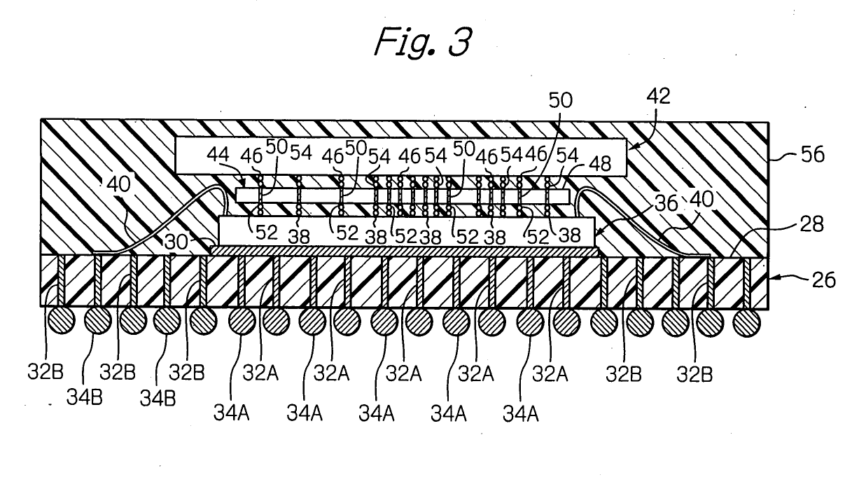

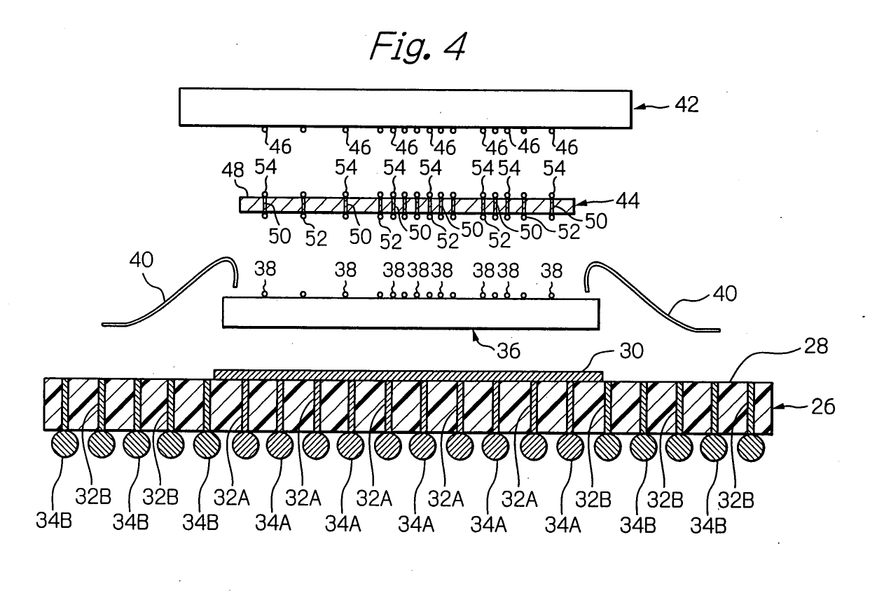

With reference to FIGS. 3 and 4, a first embodiment of a COC type three-dimensional semiconductor package according to the present invention will be now explained.

For manufacturing the COC type three-dimensional semiconductor package shown in FIG. 3, first, a rectangular wiring board or package board 26 is prepared. This package board 26 comprises a board body 28 which is composed of a suitable insulating material, such as epoxy-based resin, polyimide-base resin, polyamide-based resin, glass epoxy, ceramic or the like. Optionally, the board body 28 may be made from an insulating tape composed of a suitable resin material, such as epoxy-based resin, polyimide-base resin, polyamide-based resin or the like. Note, in FIGS. 3 and 4, the package board 26 is shown in a cross-sectional view.

In this embodiment, the package board 26 has a heat-spreader layer 30 formed on a top surface of the board body 28 at a central area thereof, and the heat-spreader layer 30 is composed of a suitable metal material exhibiting a superior thermal conductivity, such as copper (Cu), aluminum (Al) or the like.

Also, the package board 26 has a plurality of heat-sink plugs 32A formed in the central area of the board body 28, and a plurality of via plugs 32B formed in a rectangular peripheral area of the board body 28 surrounding the central area thereof. The heat-sink plugs 32A and the via plugs 32B may be composed of a suitable metal material exhibiting a superior thermal conductivity, such as copper (Cu), aluminum (Al) or the like. Each of the heat-sink plugs 32A is integrally connected to the heat spreader layer 30 at its top end face. Each of the via plugs 32B is exposed to the outside at its top end face, and the top end face serves as an electrode terminal or pad.

As shown in FIGS. 3 and 4, the package board 26 is provided with a plurality of metal balls 34A bonded to the heat-sink plugs 32A at their bottom end faces, and a plurality of metal balls 34B bonded to the via plugs 32B at their bottom end face. The metal balls 34A and 34B are identical to each other, and are composed of a suitable metal material, such as gold (Au), copper (Cu), lead/tin alloy (Pb/Sn) or the like. In short, the package board 26 is formed for being used in a ball grid array (BGR) type semiconductor package. Note, in this embodiment, each of the metal balls 34A serves as a heat-sink ball.

After the preparation of the package board 26, a rectangular semiconductor chip 36 is prepared. In this first embodiment, the semiconductor chip 36 comprises an LSI logic-circuit chip, such as an ASIC/MPU or the like. The logic-circuit chip 36 may have a rectangular area falling within a range from 5 mm² to 8 mm², and may be produced from a monocrystalline silicon wafer by using various well-known processes. Similar to the aforesaid logic-circuit chip 14, the logic-circuit chip 36 has a plurality of electrode terminals or pads (not shown) formed along peripheral sides of a top surface thereof, and a plurality of electrode terminals or pads (not shown) formed on a central area of the top surface encompassed by the peripheral electrode pads. The logic-circuit chip 14A is provided with a plurality of metal bumps 38 bonded to the electrode pads thereof, and each of the metal bumps 38 serves as an electrode terminal. Each of the metal bumps 38 is preferably composed of gold (Au), and may have a diameter falling within a range from 20 μm to 30 μm. Note, in FIGS. 3 and 4, the logic-circuit board 36 is shown in a side view.

As is apparent from FIGS. 3 and 4, the logic-circuit chip 36 is mounted on the heat-spreader layer 30 formed on the package board 26. Then, each of the peripheral electrode pads of the logic-circuit chip 36 is electrically connected to a top end face of a corresponding via plug 32B of the package board 26 by an electrical wire or bonding wire 40, using a wire bonding machine, with each of the top end faces of the via plugs 32B serving as an electrode terminal. The electrical wire 40 may be a suitable metal wire, such as a gold wire, an aluminum wire or the like. Note, a flexible wiring tape including a plurality of conductive wires may be substituted for the electrical wires 40.

Thereafter, another rectangular semiconductor chip 42 and a rectangular spacer chip 44 are prepared, and the semiconductor chip 42 is electrically attached to the logic-circuit chip 36 through the intermediary of the spacer chip 44, as best shown in FIG. 3. Note, in FIGS. 3 and 4, the semiconductor chip 42 is shown in a side view, and the spacer chip 44 is shown in a cross-sectional view.

In this first embodiment, the semiconductor chip 42 is produced as a dynamic random access memory (DRAM) of face-down (flip-chip) type from a monocrystalline silicon wafer by using various well-known processes, and has a large capacity of 256 M bits. The memory chip 42 may have a rectangular area falling within a range from 8 mm² to 10 mm². Namely, as apparent from FIGS. 3 and 4, the memory chip 42 features a larger size than that of the logic-circuit chip 36. The memory chip 42 has a plurality of electrode pads formed on a top surface thereof, with an arrangement of these electrode pads having a mirror image relationship with respect to an arrangement of the electrode pads of the logic-circuit chip 36. Also, the memory chip 42 is provided with a plurality of metal bumps 46 bonded to the electrode pads thereof, and each of the metal bumps 46 serves as an electrode terminal. Similar to the bumps 38 of the logic-circuit chip 36, each of the metal bumps 46 is preferably composed of gold (Au), and may have a diameter falling within a range from 20 μm to 30 μm.

On the other hand, the spacer chip 44 comprises a rectangular monocrystalline silicon substrate 48 which may have a thickness falling within a range from 100 μm to 130 μm, and a rectangular area falling within a range from 4 mm² to 6 mm². Namely, the spacer chip 44 has a smaller size than both the logic-circuit chip 36 and the memory chip 42. The spacer chip 44 has a plurality of via plugs 50 formed in the silicon substrate 48, and is provided with a plurality of bottom metal bumps 52 bonded to respective bottom end faces of the via plugs 50, and a plurality of top metal bumps 54 bonded to respective top end faces of the via plugs 50, and each of the bottom and top metal bumps 52 and 54 serves as an electrode terminal. Each of the via plugs 50 is composed of a suitable metal material, such as copper (Cu) or the like, and has a diameter which is on the order of 10 μm. Each of the bottom and top metal bumps 52 and 54 is preferably composed of gold (Au), and may have a diameter falling within a range from 20 μm to 30 μm. An arrangement of the bottom metal bumps 52 has a mirror image relationship with respect to the arrangement of the metal bumps 38 of the logic-circuit chip 36, and an arrangement of the top metal bumps 54 has a mirror image relationship with respect to the arrangement of the metal bumps 46 of the memory chip 42. Note, the spacer chip 44 may be produced from a monocrystalline silicon wafer as stated in detail hereinafter.

Thus, as best shown in FIG. 3, the spacer chip 44 can be mounted on the logic-circuit chip 36 such that the respective bottom metal bumps 52 of the spacer chip 44 are bonded to the metal bumps 38 of the logic-circuit chip 36. Also, the memory chip 42 can be mounted on the spacer chip 44 such that the respective metal bumps 46 of the memory chip 42 are bonded to the top metal bumps 54 of the spacer chip 44 without interfering with the electrical wires or bonding wires 40, due to the intervention of the spacer chip 44 between the logic-circuit chip 36 and the memory chip 42.

Note, the bonding of the metal bumps 52 to the metal bumps 38 and the bonding of the metal bumps 46 to the metal bumps 54 may be carried out by using, for example, either an ultrasonic-pressure bonding process or a heat-pressure bonding process.

After the mounting of the memory chip 42 is completed, the logic-circuit chip 36, the spacer chip 44, and the memory chip 42 are sealed and molded with a suitable resin material, such as epoxy resin, urethane resin, phenolic resin or the like, by using, for example, a transfer molding process, to thereby produce a molded resin enveloper 56 encapsulating the chips 36, 42 and 44 together with the metal bumps 38, 46, 52 and 54. Thus, the production of the COC type semiconductor package as shown in FIG. 3 is completed. Note, in FIG. 3, the molded resin enveloper 56 is shown in a cross-sectional view.

The aforesaid first embodiment is advantageously applied to a case where each of the logic-circuit and memory chips 36 and 42 is produced as a general-purpose chip, because both the logic-circuit chip 36 and the memory chip 42 can be previously designed such that the mirror image relationship is established between the arrangement of the metal bumps 38 of the logic-circuit chip 36 and the arrangement of the metal bumps 46 of the memory chip 42.

### Second Embodiment

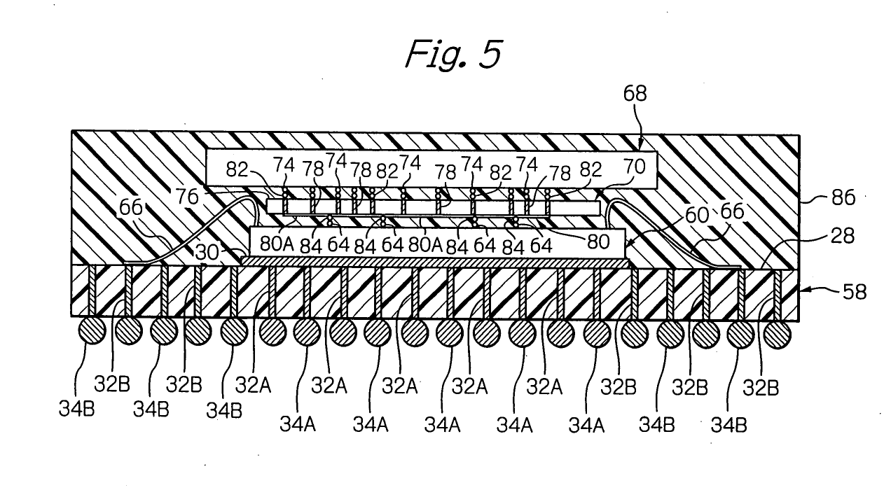

With reference to FIGS. 5 to 10, a second embodiment of the COC type three-dimensional semiconductor package according to the present invention is explained below.

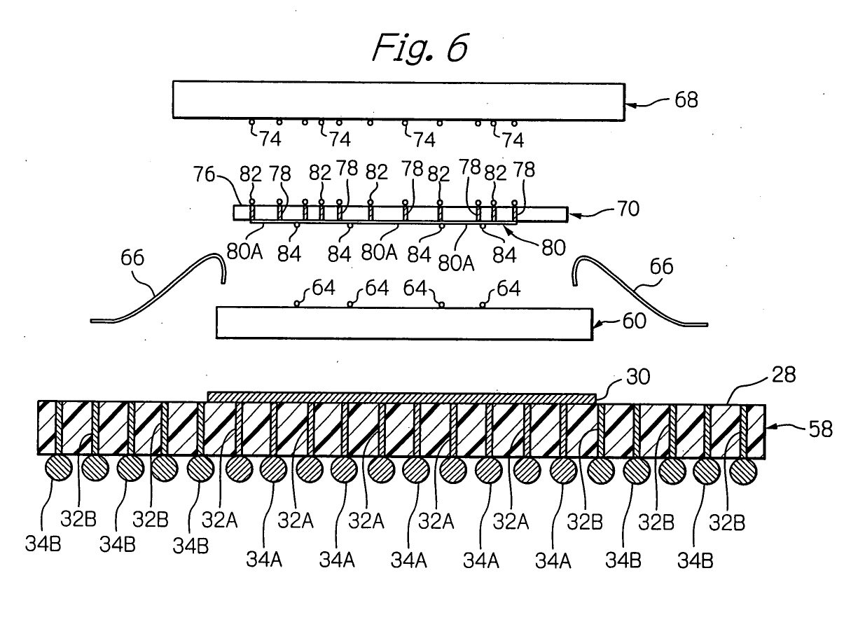

For manufacturing the COC type three-dimensional semiconductor package shown in FIG. 5, first, a rectangular wiring board or package board 58 is prepared. This package board 58 is substantially identical to the package board 26 used in the aforesaid first embodiment. In FIGS. 5 and 6, various elements forming the package board 58 are indicated by the same references as in FIGS. 3 and 4. Namely, the package board 58 comprises a board body 28, a heat-spreader layer 30 formed on a top surface of the board body 28 at a central area thereof, a plurality of heat-sink plugs 32A formed in the central area of the board body 28, and a plurality of via plugs 32B formed in a rectangular peripheral area of the board body 28 surrounding the central area thereof, each of the heat-sink plugs 32A being integrally connected to the heat spreader layer 30 at its top end face. Also, the package board 58 is provided with a plurality of metal balls 34A bonded to the heat-sink plugs 32A at their bottom end faces, and a plurality of metal balls 34B bonded to the via plugs 32B at their bottom end face. Note, in FIGS. 5 and 6, the package board 58 is shown in a cross-sectional view.

After the preparation of the package board 58, a rectangular semiconductor chip 60 is prepared. Similar to the aforesaid first embodiment, the semiconductor chip 60 comprises an LSI logic-circuit chip, such as ASIC/MPU or the like. Also, the logic-circuit chip 60 may have a rectangular area falling within a range from 5 mm² to 8 mm², and may be produced from a monocrystalline silicon wafer by using various well-known processes. Note, in FIGS. 5 and 6, the logic-circuit chip 60 is shown in a side view.

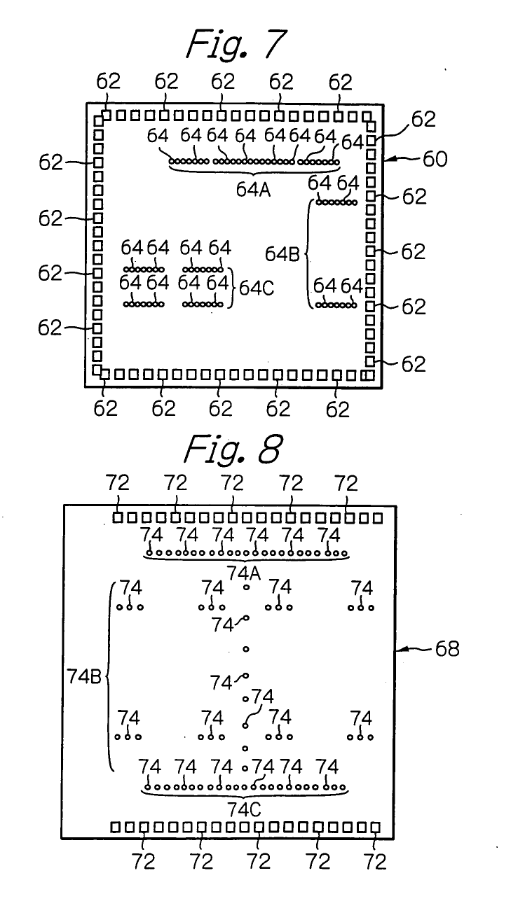

With reference to FIG. 7, the logic-circuit chip 60 is shown in a plan view. As shown in this drawing, the logic-circuit chip 60 has a plurality of electrode terminals or pads 62 formed along peripheral sides of a top surface thereof, and a plurality of electrode terminal or pads (not visible in FIG. 7) formed on a central area of the top surface encompassed by the peripheral electrode pads 62. The logic-circuit chip 60 is provided with a plurality of metal bumps 64 bonded to the electrode pads, and each of the metal bumps 64 serves as an electrode terminal. Similar to the first embodiment, each of the metal bumps 64 is preferably composed of gold (Au), and may have a diameter falling within a range from 20 μm to 30 μm.

Note, in the example shown in FIG. 7, a group of metal bumps 64, generally indicated by reference 64A, is provided as terminals for a data bus, an address bus, a control bus and so on; a group of metal bumps 64, generally indicated by reference 64B, is provided as terminals for a power supply and grounding; and a group of metal bumps 64, generally indicated by reference 64C, is provided as terminals for an input/output interface.

As is apparent from FIGS. 5 and 6, the logic-circuit chip 60 is mounted on the heat-spreader layer 30 formed on the package board 58. Then, each of the peripheral electrode pads 62 of the logic-circuit chip 60 is electrically connected to a top end face of a corresponding via plug 32B of the package board 58 by an electrical wire or bonding wire 66, which may be a suitable metal wire, such as a gold wire, an aluminum wire or the like.

Thereafter, another semiconductor device 68 and a rectangular spacer chip 70 are prepared, and the semiconductor chip 68 is electrically attached to the logic-circuit chip 60 through the intermediary of the spacer chip 70, as best shown in FIG. 5. Similar to the aforesaid first embodiment, the semiconductor chip 68 is produced as a DRAM of face-down (flip-chip) type from a monocrystalline silicon wafer by using various well-known processes, and has a large capacity of 256 M bits. Also, the memory chip 68 has a rectangular area falling within a range from 8 mm² to 10×10 mm².

With reference to FIG. 8, the memory chip 68 is shown in a plan view. As shown in this drawing, the memory chip 68 has a plurality of testing pads 72 formed along opposite sides of a top surface thereof, and a plurality of electrode pads (not visible in FIG. 8) formed on a central area of the top surface thereof. The memory chip 68 is provided with a plurality of metal bumps 74 bonded to the electrode pads, and each of the metal bumps 74 serves as an electrode terminal. Similar to the first embodiment, each of the metal bumps 74 is preferably composed of gold (Au), and may have a diameter falling within a range from 20 μm to 30 μm.

Note, the testing pads 72 are used for testing the memory chip 68 after the production thereof. Also, note, in the example shown in FIG. 8, a group of metal bumps 74, generally indicated by reference 74A, is provided as terminals for a data bus, an address bus, a control bus and so on; a group of metal bumps 74, generally indicated by reference 74B, is provided as terminals for a power supply and a grounding; and a group of metal bumps 74, generally indicated by reference 74C, is provided as terminals for an input/output interface, a power supply, and a grounding.

Similar to the aforesaid first embodiment, the spacer chip 70 comprises a rectangular monocrystalline silicon substrate 76 having a thickness falling within a range from 100 μm to 130 μm, and a rectangular area falling within a range from 4 mm² to 6 mm². Also, the spacer chip 70 has a plurality of via plugs 78 formed in the silicon substrate 76, and a wiring layout pattern 80 formed on a bottom surface of the silicon substrate 76 and electrically connected to bottom end faces of the via plugs 78. Similar to the aforesaid via plugs 50, each of the via plugs 78 is composed of a suitable metal material, such as copper (Cu) or the like, and has a diameter which is on the order of 10 μm. Also, the wiring layout pattern 80 is formed of a suitable metal material, such as copper (Cu), aluminum (Al) or the like, and includes a plurality of conductive paths 80A, each of which has a width falling within a range from 1 μm to 2 μm. The spacer chip 70 is provided with a plurality of top metal bumps 82 bonded to respective top end faces of the via plugs 78, and a plurality of bottom metal bumps 84 suitably arranged and bonded to the wiring layout pattern 80, and each of the top and bottom metal bumps 82 and 84 serves as an electrode terminal. Note, the spacer chip 70 may be produced from a monocrystalline silicon wafer as stated in detail hereinafter.

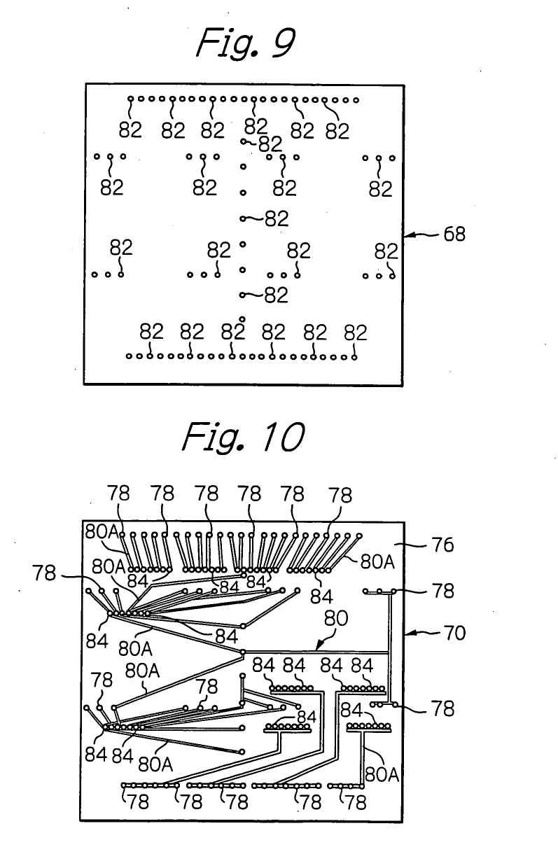

With reference to FIG. 9, the spacer chip 70 is shown in a top plan view. As is apparent from FIGS. 8 and 9, the top metal bumps 82 of the spacer chip 70 are arranged so as to have a mirror image relationship with respect to an arrangement of the metal bumps 74 of the memory chip 68. Namely, the via plugs 78 are arranged so as to have a mirror image relationship with respect to the arrangement of the metal bumps 74 of the memory chip 68.

On the other hand, with reference to FIG. 10, the spacer chip 70 is shown in a bottom plan view. As is apparent from FIGS. 7 and 10, the bottom metal bumps 84 are arranged so as to have a mirror image relationship with respect an arrangement of the metal bumps 64 of the logic-circuit chip 60. In other words, the wiring layout pattern 80 is designed so as to obtain the mirror image relationship between the arrangement of the bottom metal bumps 64 of the logic-circuit chip 64 and the arrangement of the metal bumps 84 of the spacer chip 70, with the metal bumps 84 being suitably and electrically connected to the bottom end faces of the via plugs 78 through the conductive paths 80A forming the wiring layout pattern 80.

Thus, as best shown in FIG. 5, the spacer chip 70 can be mounted on the logic-circuit chip 36 such that the respective bottom metal bumps 84 of the spacer chip 70 are bonded to the metal bumps 64 of the logic-circuit chip 60. Also, the memory chip 68 can be mounted on the spacer chip 70 such that the respective metal bumps 74 of the memory chip 68 are bonded to the top metal bumps 82 of the spacer chip 70 without interfering with the electrical wires or bonding wires 66 due to the intervention of the spacer chip 70 between the logic-circuit chip 60 and the memory chip 68.

After the mounting of the memory chip 68 is completed, the logic-circuit chip 60, the spacer chip 70 and the memory chip 68 are sealed and molded with a suitable resin material, such as epoxy resin, urethane resin, phenolic resin or the like, by using, for example, a transfer molding process, to thereby produce a mold resin enveloper 86 encapsulating the logic-circuit chip 60, the spacer chip 70 and the memory chip 68 together with the metal bumps 64, 74, 82 and 84. Thus, the production of the COC type three-dimensional semiconductor package as shown in FIG. 5 is completed. Note, in FIG. 5, the molded resin enveloper 86 is shown in a cross-sectional view.

This second embodiment is advantageously applied to a case where one of the logic-circuit chip 60 and the memory chip 68 is produced as either a specific-purpose chip or a custom-made chip.

In particular, for example, when the logic-circuit chip 60 is produced as the specific-purpose chip or custom-made chip, and when the memory chip 68 is produced as a general-purpose chip, a multi-layered wiring arrangement of the logic-circuit chip 60 must include an additional uppermost wiring layout layer, which is designed such that the arrangement of the metal bumps (64) of the logic-circuit chip 60 has the mirror image relationship with respect to the arrangement of the metal bumps 74 of the general-purpose memory chip 68, to thereby establish the electrical connections therebetween. Nevertheless, in the aforesaid second embodiment, it is possible to eliminate the additional uppermost wiring layout layer from the multi-layered arrangement of the logic-circuit chip 60, because the spacer chip 70 is substituted for the additional uppermost wiring layout layer, i.e. because the spacer chip 70 makes it possible to establish the electrical connections between the arrangement of the metal bumps 64 of the logic-circuit chip 60 and the arrangement of the metal bumps 74 of the general-purpose memory chip 68. Thus, not only can production cost of the logic-circuit chip 60 be reduced, but also freedom of the design of the logic-circuit chip 60 can be enhanced.

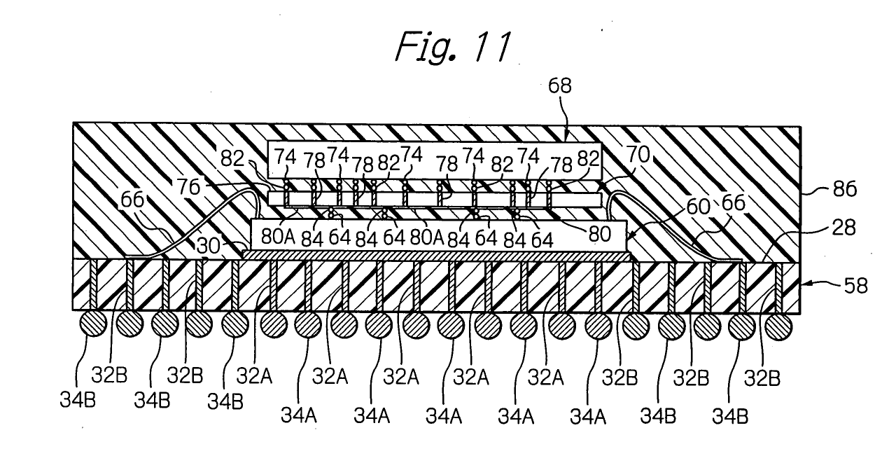

FIG. 11 shows a modification of the second embodiment shown in FIGS. 5 to 10. Note, in FIG. 11, the same references as in FIG. 5 represent the same elements.

In this modified embodiment, the memory chip 68 may have a size which is equivalent to or smaller than that of the logic-circuit chip 60. Namely, for example, the memory chip 68 may be produced as a dynamic random access memory chip having a capacity of 128 M bits. In short, in the modified embodiment, the spacer chip 70 is utilized only for the purpose of establishing the electrical connections between the arrangement of the metal bumps 64 of the logic-circuit chip 60 and the arrangement of the metal bumps 74 of the general-purpose memory chip 42.

### Third Embodiment

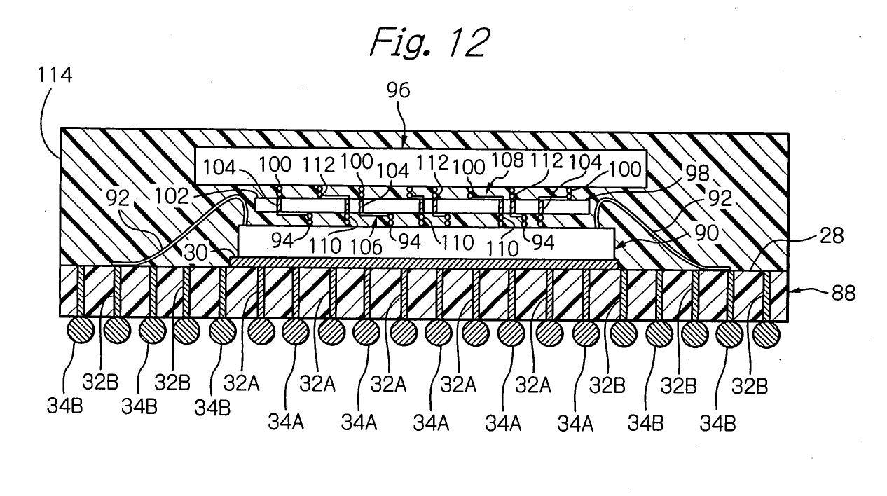

With reference to FIG. 12, a third embodiment of the COC type three-dimensional semiconductor package according to the present invention is explained below.

In this third embodiment, the COC type three-dimensional semiconductor package includes a rectangular wiring board or package board 88 which is substantially identical to the package board 26 used in the aforesaid first embodiment. Note, in FIG. 12, various elements forming the package board 88 are indicated by the same references as in FIG. 3. Also, note, in FIG. 12, the package board 88 is shown in a cross-sectional view.

Similar to the above-mentioned first and second embodiments, the COC type semiconductor package includes a rectangular semiconductor chip or logic-circuit chip 90 which is securely mounted on the heat-spreader layer 30 formed on the package body 28 of the package board 88. The logic-circuit chip 90 has a plurality of electrode terminals or pads (not shown) formed along peripheral sides of a top surface thereof, and each of the peripheral electrode pads of the logic-circuit chip 90 is electrically connected to a top end face of a corresponding via plug 32B of the package board 88 by an electrical wire or bonding wire 92, using a wire bonding machine. Also, the logic-circuit chip 90 has a plurality of electrode pads (not shown) formed on the top surface thereof, and is provided with a plurality of metal bumps 94 which are respectively bonded to the electrode pads, with each of the metal bumps 94 serving as an electrode terminal. Note, in FIG. 12, the logic-circuit chip 90 is shown in a side view.

Similar to the above-mentioned first and second embodiments, in this third embodiment, a rectangular semiconductor chip or memory chip 96 is electrically attached to the logic-circuit chip 90 through the intermediary of a rectangular spacer chip 98. The memory chip 96 is of a face-down (flip-chip) type, and is produced as a DRAM chip, having a large capacity of 256 M bits, from a monocrystalline silicon wafer by using various well-known processes. Also, the spacer chip 98 may be produced from a monocrystalline silicon wafer as stated in detail hereinafter. Note, in FIG. 12, the memory chip 96 is shown in a side view, and the spacer chip 98 is shown in a cross-sectional view.

In the third embodiment, the logic-circuit chip 90 and the memory chip 96 may be freely designed and produced as being independent from each other. Namely, it is possible to design and produce one of the semiconductor chips 90 and 98 without being subjected to any limitations by a design of the other semiconductor chip, because the spacer chip 98 is designed so as to establish electrical connections between the logic-circuit chip 90 and the memory chip 96.

In particular, the memory chip 96 is of a face-down (flip-chip) type, and has a plurality of electrode pads (not shown) formed on a top surface thereof. The memory chip 96 is provided with a plurality of metal bumps 100 bonded to the electrode pads formed on the top surface thereof, and each of the metal bumps 100 serves as an electrode terminal.

On the other hand, the spacer chip 98 comprises a rectangular monocrystalline silicon substrate 102, a plurality of via plugs 104 formed in the silicon substrate 100, a bottom wiring layout pattern 106 formed on a bottom surface of the silicon substrate 102 and electrically connected to bottom end faces of the via plugs 104, and a top wiring layout pattern 108 formed on a top surface of the silicon substrate 102 and electrically connected to top end faces of the via plugs 104. The spacer chip 98 is provided with a plurality of bottom metal bumps 110, which are suitably arranged and bonded to the bottom wiring layout pattern 106 such that an arrangement of the bottom metal bumps 110 has a mirror image relationship with respect to an arrangement of the metal bumps 94 of the logic-circuit chip 90. Also, the spacer chip 98 is provided with a plurality of top metal bumps 112, which are suitably arranged and bonded to the top wiring layout pattern 108 such that an arrangement of the top metal bumps 112 has a mirror image relationship with respect to an arrangement of the metal bumps 100 of the memory chip 96. Note, each of the metal bumps 110 and 112 serves as an electrode terminal.

Thus, as shown in FIG. 12, the spacer chip 98 can be mounted on the logic-circuit chip 90 such that the respective bottom metal bumps 110 of the spacer chip 98 are bonded to the metal bumps 94 of the logic-circuit chip 90. Also, the memory chip 96 can be mounted on the spacer chip 98 such that the respective metal bumps 100 of the memory chip 96 are bonded to the top metal bumps 112 of the spacer chip 98.

After the mounting of the memory chip 96 is completed, the logic-circuit chip 90, the spacer chip 98 and the memory chip 96 are sealed and molded with a suitable resin material, such as epoxy resin, urethane resin, phenolic resin or the like, by using, for example, a transfer molding process, to thereby produce a mold resin enveloper 114 encapsulating the chips 90, 96 and 98 together with the metal bumps 94, 100, 110 and 112. Thus, the production of the COC type three-dimensional semiconductor package as shown in FIG. 12 is completed. Note, in FIG. 12, the molded resin enveloper 114 is shown in a cross-sectional view.

### Fourth Embodiment

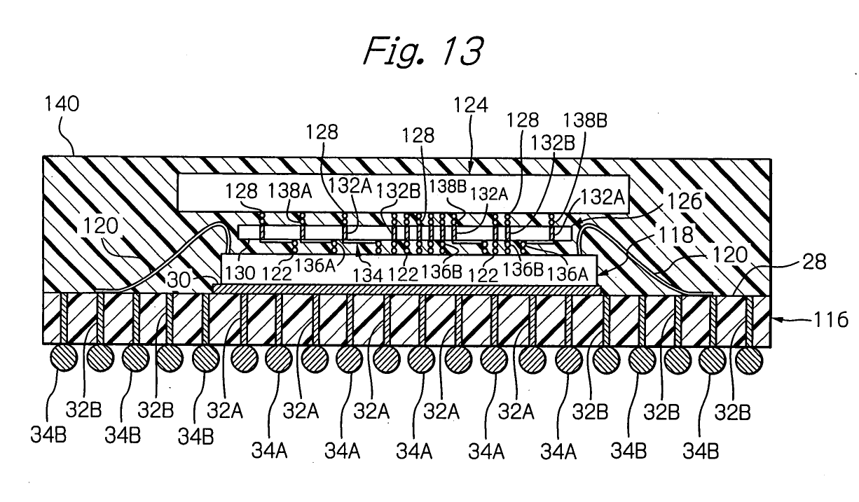

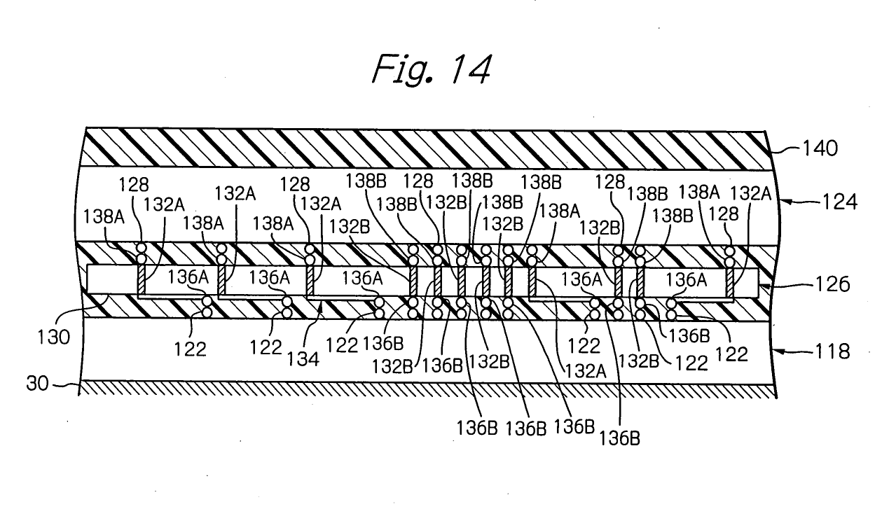

With reference to FIGS. 13 and 14, a fourth embodiment of the COC type three-dimensional semiconductor package according to the present invention is explained below.

In this fourth embodiment, the COC type three-dimensional semiconductor package includes a rectangular wiring board or package board 116 which is substantially identical to the package board 26 used in the aforesaid first embodiment. Note, in FIG. 13, various elements forming the package board 116 are indicated by the same references as in FIG. 3. Also, note, in FIG. 13, the package board 116 is shown in a cross-sectional view.

Similar to the above-mentioned first, second and third embodiments, the COC type semiconductor package includes a rectangular semiconductor chip or logic-circuit chip 118 which is securely mounted on the heat-spreader layer 30 formed on the package body 28 of the package board 116. The logic-circuit chip 118 has a plurality of electrode terminals or pads (not shown) formed along peripheral sides of a top surface thereof, and each of the peripheral electrode pads of the logic-circuit chip 118 is electrically connected to a top end face of a corresponding via plug 32B of the package board 118 by an electrical wire or bonding wire 120, using a wire bonding machine. Also, the logic-circuit chip 118 has a plurality of electrode pads (not shown) formed on the top surface thereof, and is provided with a plurality of metal bumps 122 which are respectively bonded to the electrode pads, with each of the metal bumps 122 serving as an electrode terminal. Note, in FIGS. 13 and 14, the logic-circuit chip 118 is shown in a side view.

Similar to the above-mentioned first, second and third embodiments, in this fourth embodiment, a rectangular semiconductor chip or memory chip 124 is electrically attached to the logic-circuit chip 118 through the intermediary of a rectangular spacer chip 126. The memory chip 124 is of a face-down (flip-chip) type, and is produced as a DRAM chip, having a large capacity of 256 M bits, from a monocrystalline silicon wafer by using various well-known processes. Also, the spacer chip may be produced as stated in detail hereinafter. Note, in FIGS. 13 and 14, the memory chip 124 is shown in a side view, and the spacer chip 126 is shown in a cross-sectional view.

In particular, the memory chip 124 has a plurality of electrode pads (not shown) formed on a top surface thereof, and is provided with a plurality of metal bumps 128 bonded to the electrode pads formed on the top surface thereof, with each of the metal bumps 128 serving as an electrode terminal.

On the other hand, the spacer chip 126 comprises a rectangular monocrystalline silicon substrate 130, a plurality of via plugs 132A formed in the silicon substrate 130, a plurality of via plugs 132B formed in the silicon substrate 130, and a bottom wiring layout pattern 134 formed on a bottom surface of the silicon substrate 130 and electrically connected to bottom end faces of the via plugs 132A, as best shown in FIG. 14. Also, the spacer chip 126 is provided with a plurality of bottom metal bumps 136A suitably bonded to the bottom wiring layout pattern 134, a plurality of bottom metal bumps 136B bonded to respective bottom end faces of the via plugs 132B, a plurality of top metal bumps 138A bonded to respective top end faces of the via plugs 132A, and a plurality of top metal bumps 138B bonded to respective top end faces of the via plugs 132B, as best shown in FIG. 14. Note, each of the metal bumps 132A, 132B, 136A and 136B serves as an electrode terminal.

Similar to the above-mentioned first, second and third embodiments, there is a mirror image relationship between an arrangement of the metal bumps 122 of the logic-circuit chip 118 and an arrangement of the bottom metal bumps 136A and 136B of the spacer chip 126, and there is a mirror image relationship between an arrangement of the metal bumps 128 of the memory chip 124 and an arrangement of the top metal bumps 138A and 138B of the spacer chip 126.

Thus, as shown in FIGS. 13 and 14, the spacer chip 126 can be mounted on the logic-circuit chip 118 such that the respective bottom metal bumps 136A and 136B of the spacer chip 126 are bonded to the metal bumps 122 of the logic-circuit chip 118. Also, the memory chip 124 can be mounted on the spacer chip 126 such that the respective metal bumps 128 of the memory chip 124 are bonded to the top metal bumps 138A and 138B of the spacer chip 126.

After the mounting of the memory chip 124 is completed, the logic-circuit chip 118, the spacer chip 126 and the memory chip 124 are sealed and molded with a suitable resin material, such as epoxy resin, urethane resin, phenolic resin or the like, by using, for example, a transfer molding process, to thereby produce a mold resin enveloper 140 encapsulating the chips 118, 124 and 126 together with the metal bumps 122, 128, 136A, 136B, 138A and 138B. Thus, the production of the COC type three-dimensional semiconductor package as shown in FIGS. 13 and 14 is completed. Note, in FIGS. 13 and 14, the molded resin enveloper 140 is shown in a cross-sectional view.

As is apparent from the foregoing, the fourth embodiment is characterized in that the bottom metal bumps 136A are bonded to the bottom end faces of the via plugs 132A through the intermediary of the bottom wiring layout pattern 134 whereas the bottom metal 136B are directly bonded to the respective bottom end faces of the via plugs 134. In other words, according to the present invention, it is possible to design the spacer chip (126) such that a part (136B) of the bottom metal bumps (136A and 136B) has a mirror image relationship with respect to a part of the metal bumps (122) of the logic-circuit chip (118).

The same is true for the top metal bumps (138A and 138B) of the spacer chip (126). Namely, in the fourth embodiment shown in FIGS. 13 and 14, although the top metal bumps (138A and 138B) are arranged so as to have the mirror image relationship with respect to the arrangement of the metal bumps (128) of the memory chip 124, a part of the top metal bumps (138A and 138B) may be electrically connected to a part of the via plugs (132A and 132B) through the intermediary of a top wiring layout pattern formed on the top surface of the spacer chip (126), to thereby establish the mirror image relationship therebetween, if necessary.

In the first, second, third and fourth embodiments, although the memory chip (42, 68, 96, 124) is produced as the DRAM chip, it may be another kind of memory chip, such as a static random access memory (SRAM) chip, a flash memory chip or the like.

### Fifth Embodiment

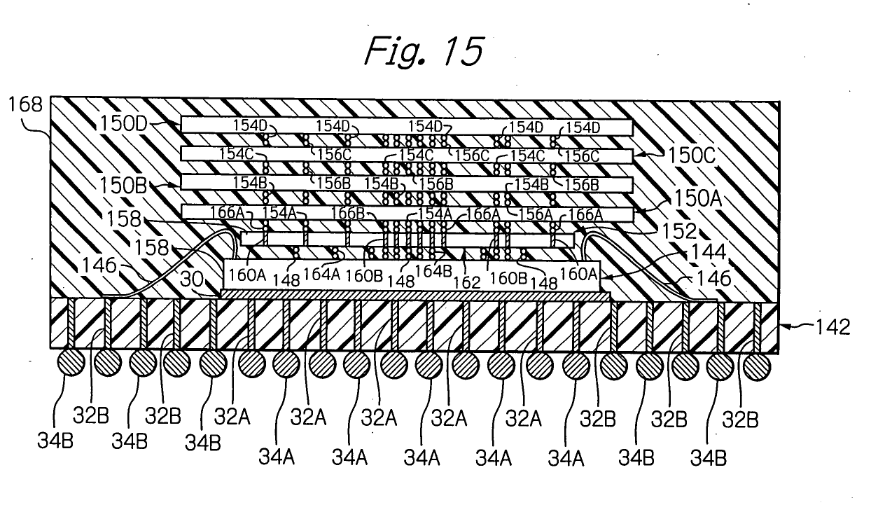

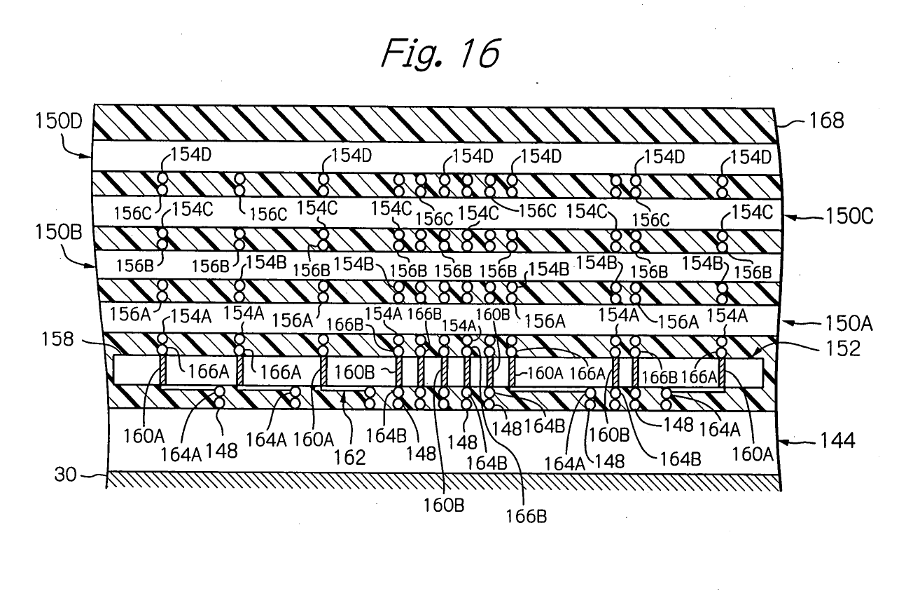

With reference to FIGS. 15 and 16, a fifth embodiment of the COC type three-dimensional semiconductor package according to the present invention is explained below.

In this fifth embodiment, the COC type three-dimensional semiconductor package includes a rectangular wiring board or package board 142 which is substantially identical to the package board 26 used in the aforesaid first embodiment. Note, in FIG. 15, various elements forming the package board 142 are indicated by the same references as in FIG. 3. Also, note, in FIG. 15, the package board 142 is shown in a cross-sectional view.

Similar to the above-mentioned first, second, third and fourth embodiments, the COC type semiconductor package includes a rectangular semiconductor chip or logic-circuit chip 144 which is securely mounted on the heat-spreader layer 30 formed on the package body 28 of the package board 142. The logic-circuit chip 144 has a plurality of electrode terminals or pads (not shown) formed along peripheral sides of a top surface thereof, and each of the peripheral electrode pads of the logic-circuit chip 144 is electrically connected to a top end face of a corresponding via plug 32B of the package board 142 by an electrical wire or bonding wire 146, using a wire bonding machine. Also, the logic-circuit chip 144 has a plurality of electrode pads (not shown) formed on the top surface thereof, and is provided with a plurality of metal bumps 148 which are respectively bonded to the electrode pads, with each of the metal bumps 148 serving as an electrode terminal. Note, in FIGS. 15 and 16, the logic-circuit chip 144 is shown in a side view.

In the fifth embodiment, the COC type semiconductor package includes four rectangular semiconductor chips: first, second, third and fourth semiconductor chips 150A, 150B, 150C and 150D, each of which may comprise an LSI memory chip, The memory chips 150A, 150B, 150C and 150D are electrically attached to the logic-circuit chip 144 through the intermediary of a rectangular spacer chip 152. Note, in FIGS. 15 and 16, each of the first, second, third and fourth memory chips 150A, 150B, 150C and 150D is shown in a side view, and the spacer chip 152 is shown in a cross-sectional view.

In particular, as shown in FIGS. 15 and 16, each of the first, second and third memory chips 150A, 150B and 150C has a plurality of bottom electrode pads (not shown) formed on a bottom surface thereof, and a plurality of top electrode pads (not shown) formed on a top surface thereof, and is provided with a plurality of bottom metal bumps (154A, 154B, 154C) bonded to the respective bottom electrodes thereof, and a plurality of top metal bumps (156A, 156B, 156C) bonded to the respective top electrode thereof, with each of the metal bumps 154A, 154B, 154C, 156A, 156B and 156C serving as an electrode terminal. The fourth memory chip 150D is of a face-down (flip-chip) type, and has a plurality of electrode pads (not shown) formed on a top surface thereof. The fourth memory chip 150D is provided with a plurality of metal bumps 156D bonded to the electrode pads formed on the top surface thereof, and each of the metal bumps 156D serves as an electrode terminal.

On the other hand, the spacer chip 152 comprises a rectangular monocrystalline silicon substrate 158, a plurality of via plugs 160A formed in the silicon substrate 158, a plurality of via plugs 160B formed in the silicon substrate 158, and a bottom wiring layout pattern 162 formed on a bottom surface of the silicon substrate 158 and electrically connected to bottom end faces of the via plugs 160A, as best shown in FIG. 16. Also, the spacer chip 152 is provided with a plurality of bottom metal bumps 164A suitably bonded to the bottom wiring layout pattern 162, a plurality of bottom metal bumps 164B bonded to respective bottom end faces of the via plugs 160B, a plurality of top metal bumps 166A bonded to respective top end faces of the via plugs 160A, and a plurality of top metal bumps 166B bonded to respective top end faces of the via plugs 160B, as best shown in FIG. 16. Note, each of the metal bumps 164A, 164B, 166A and 166B serves as an electrode terminal.

An arrangement of the bottom metal bumps 164A and 164B of the spacer chip 152 has a mirror image relationship with respect to an arrangement of the metal bumps 148 of the logic-circuit chip 144, and thus the spacer chip 152 can be mounted on the logic-circuit chip 144 such that the respective bottom metal bumps 164A and 164B of the spacer chip 152 are bonded to the metal bumps 148 of the logic-circuit chip 144, as shown in FIGS. 15 and 16. Also, an arrangement of the top metal bumps 166A and 166B of the spacer chip 152 has a mirror image relationship with respect to an arrangement of the bottom metal bumps 154A of the first memory chip 150A, and thus the first memory chip 150A can be mounted on the spacer chip 152 such that the respective bottom metal bumps 154A of the first memory chip 150A are bonded to the top metal bumps 166A and 166B of the spacer chip 152, as shown in FIGS. 15 and 16.

Further, since an arrangement of the bottom metal bumps 154B of the second memory chip 150B has a mirror image relationship with respect to an arrangement of the top metal bumps 156A of the first memory chip 150A, the second memory chip 150B can be mounted on the first memory chip 150A such that the respective bottom metal bumps 154B of the second memory chip 150B are bonded to the top metal bumps 156A of the first memory chip 150A. Similarly, since an arrangement of the bottom metal bumps 154C of the third memory chip 150C has a mirror image relationship with respect to an arrangement of the top metal bumps 156B of the second memory chip 150B, the third memory chip 150C can be mounted on the second memory chip 150B such that the respective bottom metal bumps 154C of the third memory chip 150C are bonded to the top metal bumps 156B of the second memory chip 150B.

Furthermore, since an arrangement of the metal bumps 154D of the fourth memory chip 150D has a mirror image relationship with respect to an arrangement of the top metal bumps 156C of the third memory chip 150C, the fourth memory chip 150D can be mounted on the third memory chip 150C in a face-down manner such that the respective metal bumps 154D of the fourth memory chip 150D are bonded to the top metal bumps 156C of the third memory chip 150C.

After the mounting of the fourth memory chip 150D is completed, the logic-circuit chip 144, the spacer chip 152 and the memory chips 150A to 150D are sealed and molded with a suitable resin material, such as epoxy resin, urethane resin, phenolic resin or the like, by using, for example, a transfer molding process, to thereby produce a mold resin enveloper 168 encapsulating the chips 144, 150A to 150D and 152 together with the metal bumps 148, 154A, 164A, 164B, 166A and 166B. Thus, the production of the COC type three-dimensional semiconductor package as shown in FIGS. 15 and 16 is completed. Note, in FIGS. 15 and 16, the molded resin enveloper 168 is shown in a cross-sectional view.

In the fifth embodiment, all the memory chips 150A to 150D may be the same kind of memory chips. For example, each of the memory chips 150A to 150D may be produced as a DRAM chip. Optionally, any one of the memory chips 150A to 150D may be another kind of memory chip, such an SRAM chip, a flash memory chip or the like. Further, any one of the memory chips 150A to 150D may be replaced with a logic-circuit chip which is constituted so as to cooperate with the logic-circuit chip 144.

### Sixth Embodiment

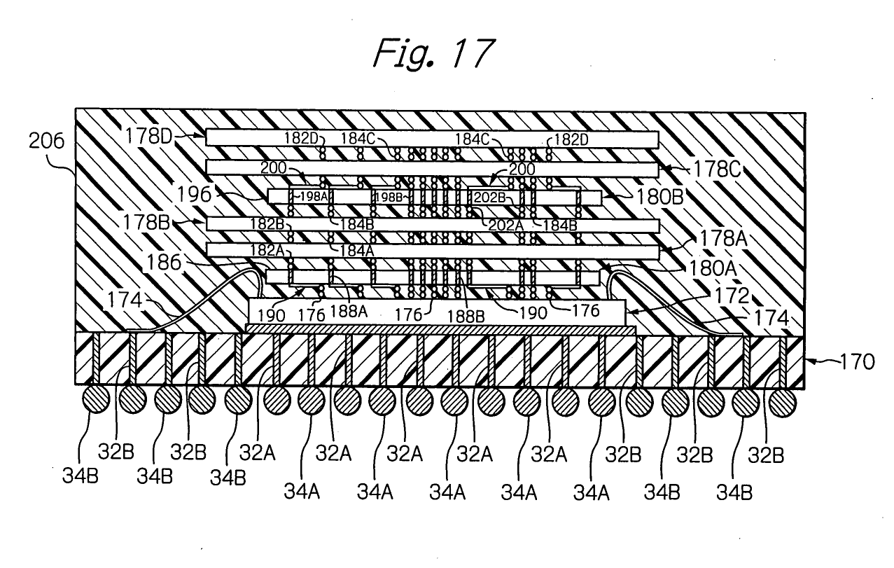

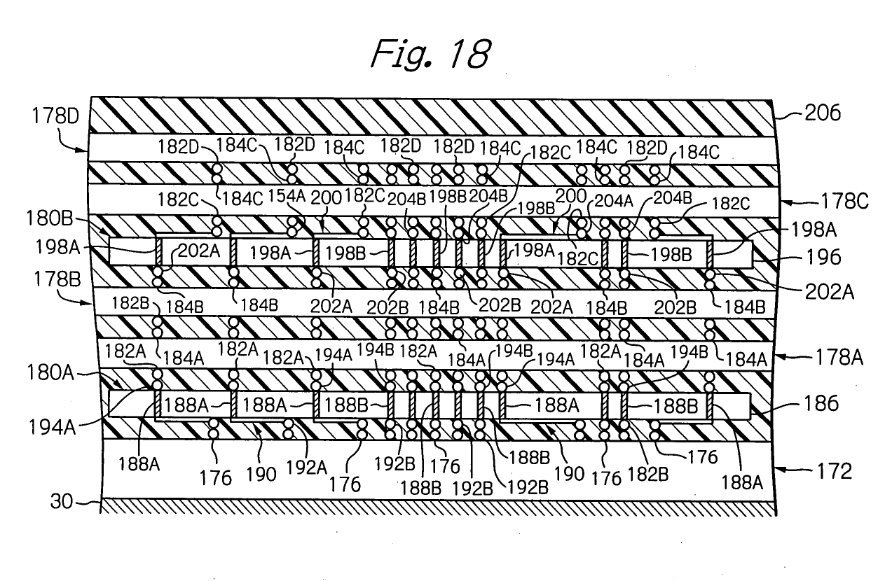

With reference to FIGS. 17 and 18, a sixth embodiment of the COC type three-dimensional semiconductor package according to the present invention is explained below.

In this sixth embodiment, the COC type three-dimensional semiconductor package includes a rectangular wiring board or package board 170 which is substantially identical to the package board 26 used in the aforesaid first embodiment. Note, in FIG. 17, various elements forming the package board 170 are indicated by the same references as in FIG. 3. Also, note, in FIG. 17, the package board 170 is shown in a cross-sectional view.

Similar to the above-mentioned first, second, third, fourth and fifth embodiments, the COC type semiconductor package includes a rectangular semiconductor chip or logic-circuit chip 172 which is securely mounted on the heat-spreader layer 30 formed on the package body 28 of the package board 172. The logic-circuit chip 172 has a plurality of electrode terminals or pads (not shown) formed along peripheral sides of a top surface thereof, and each of the peripheral electrode pads of the logic-circuit chip 172 is electrically connected to a top end face of a corresponding via plug 32B of the package board 170 by an electrical wire or bonding wire 174, using a wire bonding machine. Also, the logic-circuit chip 172 has a plurality of electrode pads (not shown) formed on the top surface thereof, and is provided with a plurality of metal bumps 176 which are respectively bonded to the electrode pads, with each of the metal bumps 176 serving as an electrode terminal. Note, in FIGS. 17 and 18, the logic-circuit chip 172 is shown in a side view.

In the sixth embodiment, the COC type semiconductor package includes first, second, third and fourth rectangular semiconductor chips or LSI memory chips 178A, 178B, 178C and 178D, and first and second rectangular spacer chips 180A and 180B associated therewith. Namely, the first and second memory chips 178A and 178B are electrically attached to the logic-circuit chip 172 through the intermediary of the first spacer chip 178A, and the third and fourth memory chips 178C and 178D are electrically attached to the logic-circuit 172 through the intermediary of the second spacer chip 180B, the first and second memory chips 178B and 178A, and the first spacer chip 180A in order. Note, in FIGS. 17 and 18, each of the first, second, third and fourth memory chips 178A, 178B, 178C and 178D is shown in a side view, and each of the first and second spacer chips 180A and 180B is shown in a cross-sectional view.

In particular, as shown in FIGS. 17 and 18, each of the first, second and third memory chips 178A, 178B and 178C has a plurality of bottom electrode pads (not shown) formed on a bottom surface thereof, and a plurality of top electrode pads (not shown) formed on a top surface thereof, and is provided with a plurality of bottom metal bumps (182A, 182B, 182C) bonded to the respective bottom electrodes thereof, and a plurality of top metal bumps (184A, 184B, 184C) bonded to the respective top electrode thereof, with each of the metal bumps 182A, 182B, 182C, 184A, 184B and 184C serving as an electrode terminal. The fourth memory chip 178D is of a face-down (flip-chip) type, and has a plurality of electrode pads (not shown) formed on a top surface thereof. The fourth memory chip 178D is provided with a plurality of metal bumps 182D bonded to the electrode pads formed on the top surface thereof, and each of the metal bumps 182D serves as an electrode terminal.

On the other hand, the first spacer chip 180A comprises a rectangular monocrystalline silicon substrate 186, a plurality of via plugs 188A formed in the silicon substrate 186, a plurality of via plugs 188B formed in the silicon substrate 186, and a bottom wiring layout pattern 190 formed on a bottom surface of the silicon substrate 186 and electrically connected to bottom end faces of the via plugs 188A, as best shown in FIG. 18. Also, the first spacer chip 180A is provided with a plurality of bottom metal bumps 192A suitably bonded to the bottom wiring layout pattern 190, a plurality of bottom metal bumps 192B bonded to respective bottom end faces of the via plugs 188B, a plurality of top metal bumps 194A bonded to respective top end faces of the via plugs 188A, and a plurality of top metal bumps 194B bonded to respective top end faces of the via plugs 188B, as best shown in FIG. 18. Note, each of the metal bumps 192A, 192B, 194A and 194B serves as an electrode terminal.

The second spacer chip 180B comprises a rectangular monocrystalline silicon substrate 196, a plurality of via plugs 198A formed in the silicon substrate 196, a plurality of via plugs 198B formed in the silicon substrate 196, and a top wiring layout pattern 200 formed on a top surface of the silicon substrate 196 and electrically connected to top end faces of the via plugs 198A, as best shown in FIG. 18. Also, the second spacer chip 180B is provided with a plurality of bottom metal bumps 202A suitably bonded to respective bottom end faces of the via plugs 198A, a plurality of bottom metal bumps 202B bonded to respective bottom end faces of the via plugs 198B, a plurality of top metal bumps 204A suitably bonded to the top wiring layout pattern 200, and a plurality of top metal bumps 204B bonded to respective top end faces of the via plugs 198B, as best shown in FIG. 18. Note, each of the metal bumps 202A, 202B, 204A and 204B serves as an electrode terminal.

An arrangement of the bottom metal bumps 192A and 192B of the first spacer chip 180A has a mirror image relationship with respect to an arrangement of the metal bumps 176 of the logic-circuit chip 172, and thus the first spacer chip 180A can be mounted on the logic-circuit chip 172 such that the respective bottom metal bumps 192A and 192B of the first spacer chip 180A are bonded to the metal bumps 176 of the logic-circuit chip 172, as shown in FIGS. 17 and 18. Also, an arrangement of the top metal bumps 194A and 194B of the first spacer chip 180A has a mirror image relationship with respect to an arrangement of the bottom metal bumps 182A of the first memory chip 178A, and thus the first memory chip 178A can be mounted on the first spacer chip 180A such that the respective bottom metal bumps 182A of the first memory chip 178A are bonded to the top metal bumps 194A and 194B of the first spacer chip 180A, as shown in FIGS. 17 and 18. Further, since an arrangement of the bottom metal bumps 182B of the second memory chip 178B has a mirror image relationship with respect to an arrangement of the top metal bumps 184A of the first memory chip 178A, the second memory chip 178B can be mounted on the first memory chip 178A such that the respective bottom metal bumps 182B of the second memory chip 178B are bonded to the top metal bumps 184A of the first memory chip 178A.

An arrangement of the bottom metal bumps 202A and 202B of the second spacer chip 180B has a mirror image relationship with respect to an arrangement of the top metal bumps 184B of the second memory chip 178B, and thus the second spacer chip 180B can be mounted on the second memory chip 178B such that the respective bottom metal bumps 202A and 202B of the second spacer chip 180B are bonded to the metal bumps 184B of the second memory chip 178B, as shown in FIGS. 17 and 18. Also, an arrangement of the top metal bumps 204A and 204B of the second spacer chip 180B has a mirror image relationship with respect to an arrangement of the bottom metal bumps 182C of the third memory chip 178C, and thus the third memory chip 178C can be mounted on the second spacer chip 180B such that the respective bottom metal bumps 182C of the third memory chip 178C are bonded to the top metal bumps 204A and 204B of the second spacer chip 180B, as shown in FIGS. 17 and 18. Further, since an arrangement of the metal bumps 182D of the fourth memory chip 178D has a mirror image relationship with respect to an arrangement of the top metal bumps 184C of the third memory chip 178C, the fourth memory chip 178D can be mounted on the third memory chip 0.178C in a face-down manner such that the respective metal bumps 182D of the fourth memory chip 178D are bonded to the top metal bumps 184C of the third memory chip 178C.

After the mounting of the fourth memory chip 178D is completed, the logic-circuit chip 172, the first spacer chip 180A, the first and second memory chips 178A and 178B, the second spacer chip 180B, and the third and fourth memory chips 178C and 178D are sealed and molded with a suitable resin material, such as epoxy resin, urethane resin, phenolic resin or the like, by using, for example, a transfer molding process, to thereby produce a mold resin enveloper 206 encapsulating the chips 172, 178A to 178D, 180A and 180B together with the metal bumps 176, 182A to 182D, 184A to 184C, 192A, 192B, 194A, 194B, 202A, 202B, 204A and 204B. Thus, the production of the COC type three-dimensional semiconductor package as shown in FIGS. 17 and 18 is completed. Note, in FIGS. 17 and 18, the molded resin enveloper 206 is shown in a cross-sectional view.

In the sixth embodiment, the third memory chip 178C may be produced as a specific-purpose chip or custom-made chip, and the second spacer chip 180B is utilized only for the purpose of establishing electrical connections between the arrangement of the top metal bumps 184B of the second memory chip 178B and the arrangement of the bottom metal bumps 182C of the third memory chip 178C.

Similar to the above-mentioned fifth embodiment, in the sixth embodiment, all the memory chips 178A to 178D may be the same kind of memory chips. For example, each of the memory chips 178A to 178D may be produced as a DRAM chip. Optionally, any one of the memory chips 178A to 178D may be another kind of memory chip, such an SRAM chip, a flash memory chip or the like. Further, any one of the memory chips 178A to 178D may be replaced with a logic-circuit chip which is constituted so as to cooperate with the logic-circuit chip 172.

In all the above-mentioned embodiments, when one chip is mounted on another chip, a metal bump provided on the one chip is electrically bonded to a counter metal bump provided on the other chip. Nevertheless, the counter metal bump may be omitted from the other chip, if necessary.

In particular, for example, in the first embodiment shown in FIGS. 3 and 4, it is possible to omit the bottom metal bumps 52 from the bottom surface of the via plugs 50 of the spacer chip 44. In this case, each of the bottom end faces of the via plugs 52 serves as an electrode terminal, and the mounting of the spacer chip 44 on the logic-circuit chip 36 is carried out such that the respective bottom end faces of the via plugs 50 are directly bonded to the metal bumps 38 of the logic-circuit chip 36. On the other hand, in the case where the metal bumps 38 are omitted from the electrode pads formed on the logic-circuit chip 36, each of the electrode pads of the logic-circuit chip 36 serves as an electrode pad, and the mounting of the spacer chip 44 on the logic-circuit chip 36 is carried out such that the respective bottom metal bumps 52 of the spacer chip 44 are directly bonded to the electrode pads formed on the logic-circuit chip 36. Note, the same is true for the mounting of the memory chip 42 on the spacer chip 44. Also, note, the same is true for each of the second, third, fourth, fifth and sixth embodiments.

Also, in all the above-mentioned embodiments, since each of the logic-circuit memory chip, the spacer chip and the memory chip is produced from the monocrystalline silicon wafer, it is possible to considerably reduce thermal stresses which may be created in the COC type three-dimensional semiconductor package due to differences of thermal expansion among the chips.

### First Embodiment of Production Method

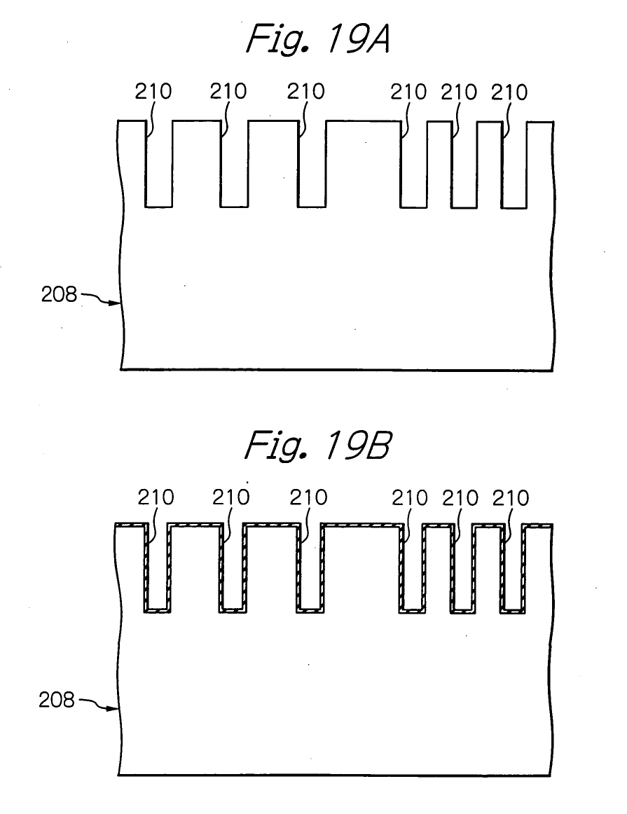

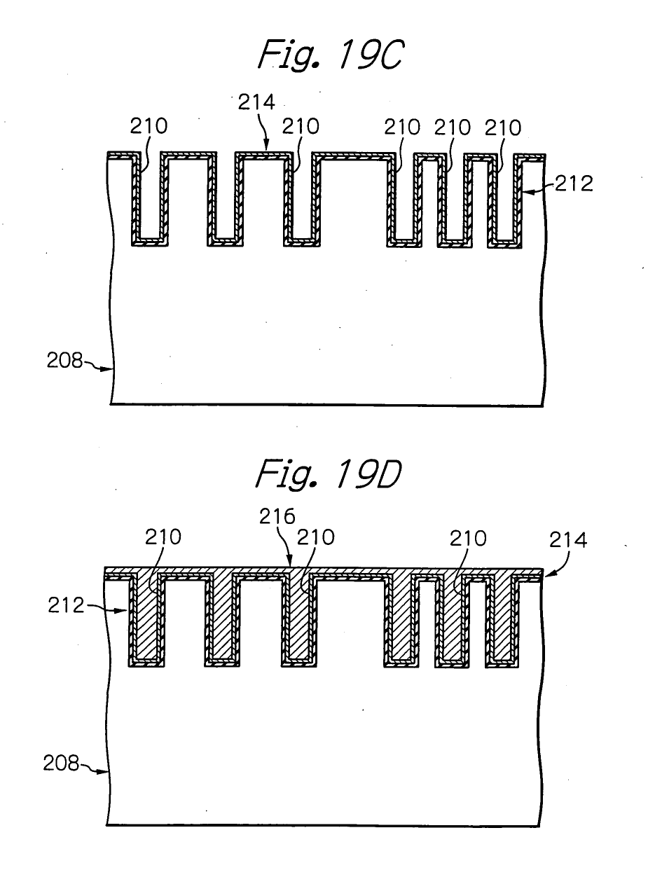

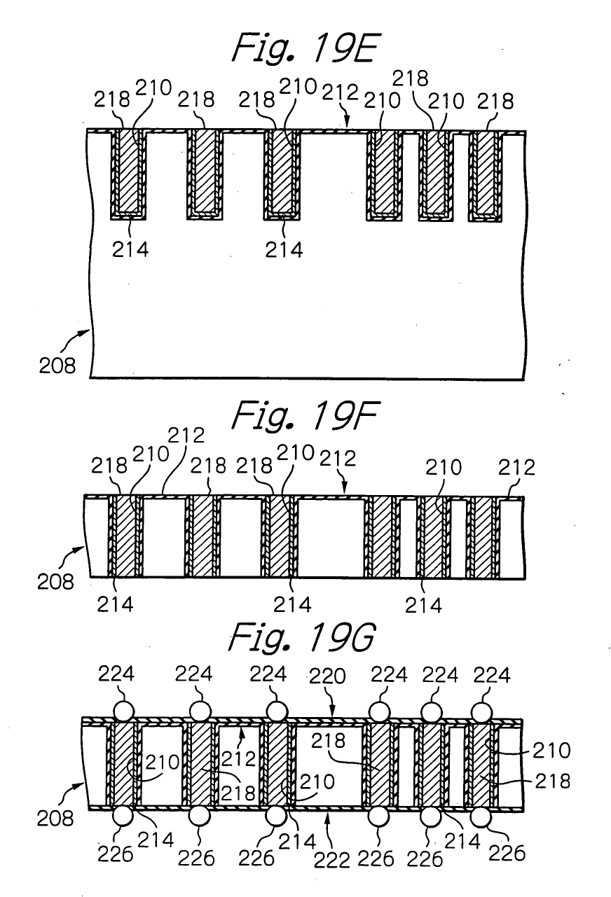

Next, with respect to FIGS. 19A to 19G, a first embodiment of a production method for producing a plurality of spacer chips, which can be used in the above-mentioned first embodiment of the COC type semiconductor package shown in FIGS. 3 and 4, is explained below.

First, as shown in FIG. 19A, a monocrystalline silicon wafer 208, a top surface of which is sectioned into a plurality of rectangular chip areas, is prepared, and a plurality of holes 210 are formed in each of the chip areas on the silicon wafer 208 by using a photolithography process and a wet or dry etching process. For example, the silicon wafer 208 has a thickness falling within a range from 700 μm to 750 μm. Also, each of the holes may have a depth falling within a range from 120 μm to 130 μm, and a diameter which is on the order of 10 μm. Note, of course, a location, at which each of the holes 210 is formed, corresponds to that of a via plug to be formed in each chip area.

After the formation of the holes 210 is completed, the silicon wafer 208 is subjected to a thermal oxidization process in which a silicon dioxide layer 212 is formed over the top surface of the silicon wafer 208, which includes inner wall surface sections defining the holes 210, as shown in FIG. 19B. Namely, the top surface of the silicon wafer 208 is reformed as the silicon dioxide layer 212.

After the formation of the silicon dioxide layer 212 is completed, the silicon wafer 208 is subjected to a sputtering process in which a barrier metal layer 214 is formed over the silicon dioxide layer 212, as shown in FIG. 19C. Note that the barrier metal layer 214 may be composed of a suitable metal material, such as titanium (Ti), titanium nitride (TiN), tantalum (Ta), tantalum nitride (TaN) or the like.

After the formation of the barrier metal layer 214 is completed, a copper (Cu) layer 216 is formed on the barrier metal layer 214 such that all the holes 210 are filled with copper (Cu), as shown in FIG. 19D. In particular, first, a copper (Cu) seed layer is formed on the barrier metal layer 214, using a sputtering process, and then the formation of the Cu layer 216 is carried out by using an electroplating process in which the Cu seed layer serves as a cathode electrode. Subsequently, the Cu layer 216 is subjected to an annealing process for crystallization.

After the annealing process is completed, the silicon wafer 208 is subjected to a chemical mechanical polishing (CMP) process in which both the Cu layer 216 and the barrier metal layer 214 are chemically and mechanically polished so that the redundant metals (Cu and e.g. Ti) are removed therefrom, as shown in FIG. 19E, to thereby form a plurality of via plugs 218 in each of the chip areas on the silicon wafer 208, with top end faces of the via plugs 218 being exposed to the outside.

After the CMP process is completed, the silicon wafer 208 is subjected to a grinding process in which the silicon wafer 208 is ground at a bottom surface thereof until bottom end faces of the via plugs 218 are exposed to the outside, as shown in FIG. 19F. Note, when the grinding process is completed, the silicon wafer 208 may have a thickness falling within a range from 120 μm to 130 μm.

After the grinding process is completed, as shown in FIG. 19G, a top passivation layer 220 is formed as a protective insulating layer on the top surface of the silicon wafer 208 such that the top end faces of the via plugs 218 are exposed to the outside. Similarly, a bottom passivation layer 222 is formed as a protective insulating layer on the bottom surface of the silicon wafer 208 such that the bottom end faces of the via plugs 218 are exposed to the outside. Then, a plurality of top metal bumps 224 are bonded to the top end faces of the via plugs 218, and a plurality of bottom metal bumps 226 are bonded to the bottom end faces of the via plugs 218. Preferably, each of the metal bumps 224 and 226 is composed of gold, and has a diameter falling within a range from 20 μm to 30 μm. The metal bumps 224 and 226 may be formed on the top and bottom end faces of the via plugs 218, using an electroplating process. Note, the formation of the top passivation layer 220 may be carried out after the CMP process is completed (FIG. 19E), if necessary.

Thereafter, the silicon wafer 208 is subjected to a dicing process, in which the chip areas defined on the silicon wafer 208 are separated from each other, resulting in production of the spacer chips, which can be used in the above-mentioned first embodiment of the COC type semiconductor package shown in FIGS. 3 and 4.

### Second Embodiment of Production Method

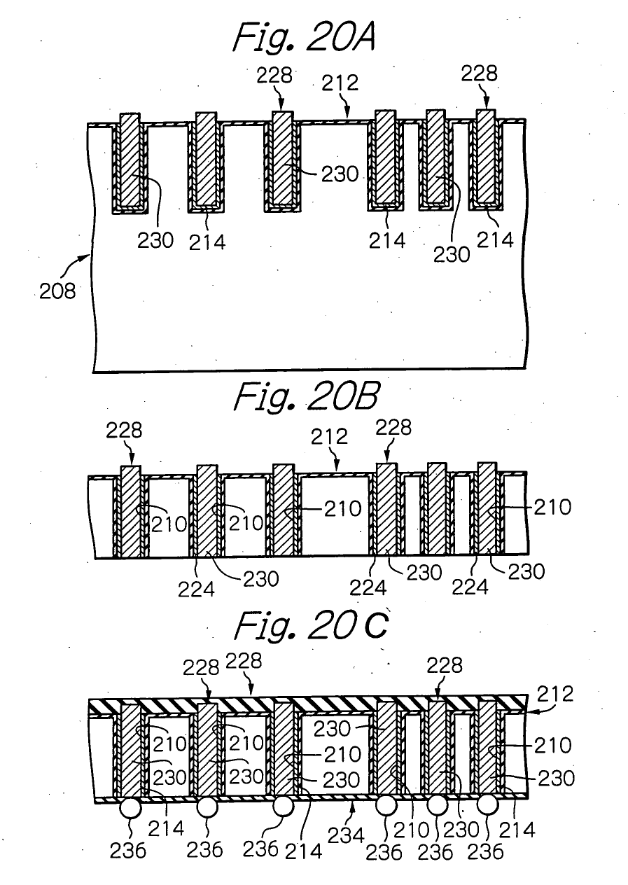

Next, with reference to FIGS. 20A to 20C, a second embodiment of a production method for producing a plurality of spacer chips, which can be used in the second embodiment of the COC type semiconductor package shown in FIGS. 5 to 10, is explained below.

Note that first, second, third and fourth representative steps of the second embodiment are substantially identical to the first, second, third and fourth steps of the first embodiment shown in FIGS. 19A to 19D. In FIG. 20A, the same references as in FIG. 19D represent the same features.

In the second embodiment, after the annealing process for the Cu layer 216 is completed (FIG. 19D), both the Cu layer 216 and the barrier metal layer 214 are patterned by using a photolithography process and a wet or dry etching process, to thereby form a wiring layout pattern 228 on the silicon wafer 208, as shown in FIG. 20A. Note, the Cu material, with which each of the holes 210 is filled, is left as a via plug 230. Although not visible in FIG. 20A, the wiring layout pattern 228 includes a plurality of conductive paths, each of which extends from a top end of a corresponding via plug 230. As explained in the description of the second embodiment of the COC type semiconductor package shown in FIGS. 5 to 10, each of the conductive paths has a width falling within a range from 1 μm to 2 μm.

After the formation of the wiring layout pattern 228 is completed, the silicon wafer 208 is subjected to a grinding process in which the silicon wafer 208 is ground at a bottom surface thereof until bottom end faces of the via plugs 230 are exposed to the outside, as shown in FIG. 20B. Note, when the grinding process is completed, the silicon wafer 208 may have a thickness falling within a range from 120 μm to 130 μm.

After the grinding process is completed, as shown in FIG. 20C, a top passivation layer 232 is formed as a protective insulating layer on the top surface of the silicon wafer 208 such that local areas (not shown) of the wiring layout pattern 228 are exposed to the outside. On the other hand, a bottom passivation layer 234 is formed as a protective insulating layer on the bottom surface of the silicon wafer 208 such that the bottom end faces of the via plugs 230 are exposed to the outside. Then, a plurality of top metal bumps (not shown) are bonded to the exposed local areas of the wiring layout pattern 228, and a plurality of bottom metal bumps 236 are bonded to the bottom end faces of the via plugs 230.

Thereafter, the silicon wafer 208 is subjected to a dicing process, in which the chip areas defined on the silicon wafer 208 are separated from each other, resulting in production of the spacer chips which can be used in the second embodiment of the COC type semiconductor package shown in FIGS. 5 to 10.

In the second embodiment of the production method according to the present invention, at least one additional wiring layout layer may be formed on the wiring layout pattern 228, if necessary. This is because there may be a case where it is difficult or impossible to establish electrical connections with respect to an LSI chip to be associated with the spacer chip concerned, by only utilizing the wiring layout pattern 228. Namely, according to the present invention, the spacer chip may be provided with a multi-layered wiring arrangement for the establishment of the electrical connections.

### Third Embodiment of Production Method

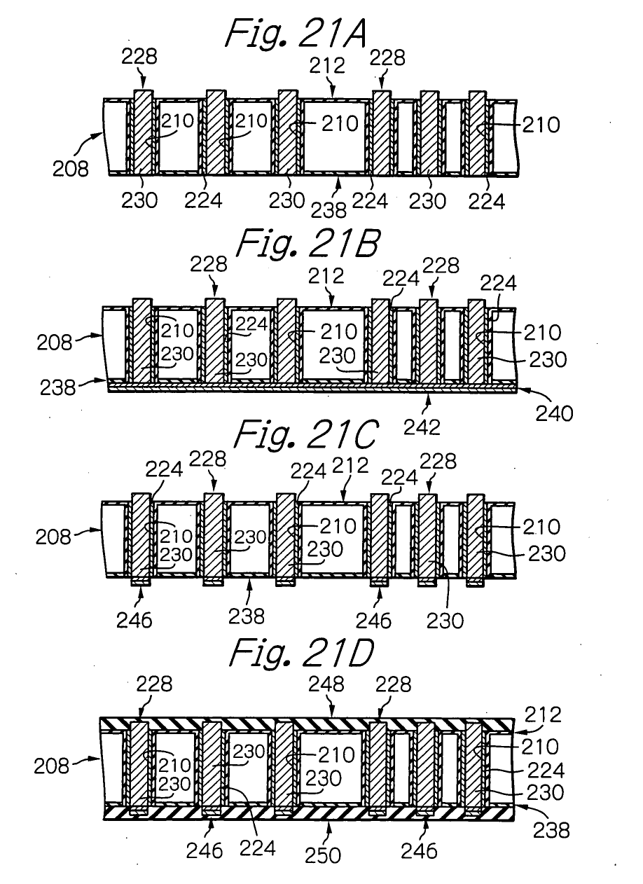

Next, with reference to FIG. 21A to 21D, a third embodiment of a production method for producing a plurality of spacer chips, which can be used in the third embodiment of the COC type semiconductor package shown in FIG. 12, is explained below.

Note that first, second, third and fourth representative steps of the third embodiment are substantially identical to the first, second, third and fourth steps of the first embodiment shown in FIGS. 19A to 19D, and that fourth and fifth representative steps of the third embodiment are substantially identical to the fourth and fifth steps of the second embodiment shown in FIGS. 20A and 20B. In FIG. 21A, the same references as in FIG. 20B represent the same features.

In the third embodiment, after the grinding process is completed (FIG. 20B), the silicon wafer 208 is subjected to a thermal oxidization process in which a silicon dioxide layer 238 is formed over the ground bottom surface of the silicon wafer 208, as shown in FIG. 21A. Namely, the ground bottom surface of the silicon wafer 208 is reformed as the silicon dioxide layer 238.

After the formation of the silicon dioxide layer 238 is completed, the silicon wafer 208 is subjected to a sputtering process in which a barrier metal layer 240 is formed over the silicon dioxide layer 238, as shown in FIG. 21B. Subsequently, a copper (Cu) layer 242 is formed on the barrier metal layer 240, as shown in FIG. 21B. In particular, first, a copper (Cu) seed layer is formed on the barrier metal layer 240, using a sputtering process, and then the formation of the Cu layer 242 is carried out by using an electroplating process in which the Cu seed layer serves as a cathode electrode. Then, the Cu layer 242 is subjected to an annealing process for crystallization. After the annealing process is completed, the silicon wafer 208 is subjected to a CMP process in which the Cu layer 242 is chemically and mechanically polished to thereby flatten a surface of the Cu layer 242.

After the CMP process is completed, both the Cu layer 242 and the barrier metal layer 240 are patterned by using a photolithography process and a wet or dry etching process, to thereby form a wiring layout pattern 246 on the bottom surface of the silicon wafer 208, as shown in FIG. 21C. Although not visible in FIG. 21C, the wiring layout pattern 246 includes a plurality of conductive paths, each of which extends from a top end of a corresponding via plug 230, with each of the conductive paths having a width falling within a range from 1 μm to 2 μm.

After the formation of the wiring layout pattern 246 is completed, as shown in FIG. 21D, a top passivation layer 248 is formed as a protective insulating layer on the top surface of the silicon wafer 208 such that local areas (not shown) of the wiring layout pattern 228 are exposed to the outside. Similarly, a bottom passivation layer 250 is formed as a protective insulating layer on the bottom surface of the silicon wafer 208 such that local areas (not shown) of the wiring layout pattern 246 are exposed to the outside. Then, a plurality of top metal bumps (not shown) are bonded to the exposed local areas of the wiring layout pattern 228, and a plurality of bottom metal bumps (not shown) are bonded to the exposed local areas of the wiring layout pattern 250.

Thereafter, the silicon wafer 208 is subjected to a dicing process, in which the chip areas defined on the silicon wafer 208 are separated from each other, resulting in production of the spacer chips which can be used in the third embodiment of the COC type semiconductor package shown in FIG. 12.

Similar to the above-mentioned second embodiment of the production method according to the present invention, at least one additional wiring layout layer may be formed on each of the wiring layout patterns 228 and 246 for the same reasons as mentioned above.

Note, it should be understood that each of the spacer chips 126, 152, 180A and 180B used in the fourth, fifth and sixth embodiments of the COC type semiconductor package can be produced by suitably modifying the first, second and third embodiments of the production method.

In the above-mentioned first, second and third embodiments of the production method according to the present invention, each of the via plugs (218, 230) composed of copper (Cu) is covered with the barrier metal layer 214, and thus copper is prevented from being diffused from the via plugs (218, 230) into a silicon body of the silicon wafer 208. Namely, the barrier metal layer 214 serves as a copper-diffusion prevention layer. Accordingly, if each of the via plugs (218, 230) is composed of another metal material, such as aluminum or the like, it is possible omit the barrier metal layers 214 from the spacer chips.

Finally, it will be understood by those skilled in the art that the foregoing description is of preferred embodiments of the packages and methods, and that various changes and modifications may be made to the present invention without departing from the spirit and scope thereof.

1. A three-dimensional semiconductor package, which comprises:
a first semiconductor chip having a plurality of top electrode terminals formed on a top surface thereon;
a spacer chip mounted on said first semiconductor chip and having a plurality of bottom electrode terminals formed on a bottom surface thereof, and a plurality of top electrode terminals formed on a top surface thereof and electrically connected to the respective bottom electrode terminals thereof, the mounting of said spacer chip on said first semiconductor chip being carried out such that the bottom electrode terminals of said spacer chip are bonded to the top electrode terminals of said first semiconductor chip, to thereby establish electrical connections therebetween; and
a second semiconductor chip mounted on said spacer chip and having a plurality of electrode terminals formed on a surface thereof, the mounting of said second semiconductor chip on said spacer chip being carried out such that the electrode terminals of said second semiconductor chip are bonded to the top electrode terminals of said spacer chip, to thereby establish electrical connections therebetween.

2. The three-dimensional semiconductor package as set forth in claim 1, further comprising a wiring board on which said first semiconductor chip is mounted, said first semiconductor chip having a plurality of peripheral electrode terminals formed along a peripheral side of the surface thereof, the mounting of said first semiconductor chip on said wiring board being carried out such that the peripheral electrode terminals of said first semiconductor chip are electrically connected to the electrode terminals of said wiring board by electrical wires.

3. The three-dimensional semiconductor package as set forth in claim 2, wherein a size of said second semiconductor chip is larger than that of said spacer chip, and the mounting of said second semiconductor chip on said spacer chip is ensured without interfering with said electrical wires, due to the intervention of the spacer chip between said first semiconductor chip and said second semiconductor chip.

4. The three-dimensional semiconductor package as set forth in claim 1, further comprising a molded resin enveloper encapsulating said first semiconductor chip, said spacer chip, and said second semiconductor chip together with the electrode terminals of said first and second semiconductor chips and said spacer chip.

5. The three-dimensional semiconductor package as set forth in claim 1, wherein said spacer chip has a plurality of via plugs which are formed therein such that respective electrical connections are established between the bottom electrode and top electrode terminals formed on the bottom and top surface of said spacer chip.

6. The three-dimensional semiconductor package as set forth in claim 5, wherein the respective bottom electrode terminals of said spacer chip are defined as bottom metal bumps bonded to bottom end faces of the via plugs.

7. The three-dimensional semiconductor package as set forth in claim 5, wherein the respective top electrode terminals of said spacer chip are defined as top metal bumps bonded to top end faces of the via plugs.

8. The three-dimensional semiconductor package as set forth in claim 5, wherein the respective bottom electrode terminals of said spacer chip are defined as bottom end faces of the via plugs.

9. The three-dimensional semiconductor package as set forth in claim 5, wherein the respective top electrode terminals of said spacer chip are defined as top end faces of the via plugs.

10. The three-dimensional semiconductor package as set forth in claim 5, wherein said via plugs are arranged such that bottom end faces of said via plugs have a mirror image relationship with respect to an arrangement of the top electrode terminals of said first semiconductor chip, and such that top end faces of said via plugs have a mirror image relationship with respect to an arrangement of the electrode terminals of said second semiconductor chip.

11. The three-dimensional semiconductor package as set forth in claim 5, wherein said spacer chip has a bottom wiring layout pattern formed on the bottom surface thereof and electrically connected to said via plugs, and said bottom electrode terminals of said spacer chip are defined on said bottom wiring layout pattern such that there is a mirror image relationship between an arrangement of the bottom electrode terminals of said spacer chip and an arrangement of the electrode terminals of said first semiconductor chip.

12. The three-dimensional semiconductor package as set forth in claim 5, wherein said spacer chip has a top wiring layout pattern formed on the top surface thereof and electrically connected to said via plugs, and said top electrode terminals of said spacer chip are defined on said top wiring layout pattern such that there is a mirror image relationship between an arrangement of the top electrode terminals of said spacer chip and an arrangement of the electrode terminals of said second semiconductor chip.

13. The three-dimensional semiconductor package as set forth in claim 5, wherein said spacer chip has a bottom wiring layout pattern formed on the bottom surface thereof and electrically connected to a part of said via plugs, and a part of the bottom electrode terminals of said spacer chip is defined on said bottom wiring layout pattern such that there is a mirror image relationship between an arrangement of the bottom electrode terminals of said spacer chip and an arrangement of the electrode terminals of said first semiconductor chip.

14. The three-dimensional semiconductor package as set forth in claim 5, wherein said spacer chip has a top wiring layout pattern formed on the top surface thereof and electrically connected to a part of said via plugs, and a part of the top electrode terminals of said spacer chip is defined on said top wiring layout pattern such that there is a mirror image relationship between an arrangement of the top electrode terminals of said spacer chip and an arrangement of the electrode terminals of said second semiconductor chip.

15. The three-dimensional semiconductor package as set forth in claim 1, further comprising another semiconductor chip on which said first semiconductor chip is mounted, said first semiconductor chip having a plurality of bottom electrode terminals formed on a bottom surface thereof, the other semiconductor chip having a plurality of top electrode terminals formed on a top surface thereof, the mounting of said first semiconductor chip on the other semiconductor chip being carried out such that the respective bottom electrode terminals of said first semiconductor chip are bonded to the top electrode terminals of the other semiconductor chip, to thereby establish electrical connections therebetween.

16. A spacer chip to be intervened between a first semiconductor chip and a second semiconductor chip to establish electrical connections therebetween, which comprises:
a substrate having a plurality of bottom electrode terminals formed on a bottom surface thereof, and a plurality of top electrode terminals formed on a top surface thereof and electrically connected to the respective bottom electrode terminals thereof; and
a plurality of via plugs formed in said substrate to establish respective electrical connections between the bottom electrode and top electrode terminals formed on the bottom and top surface of said substrate,
wherein the bottom electrode terminals of said spacer chip are arranged so as to have a mirror image relationship with respect to an arrangement of electrode terminals formed on said first semiconductor chip, and the top electrode terminals of said spacer chip are arranged so as to have a mirror image relationship with respect to an arrangement of electrode terminals formed on said second semiconductor chip.

17. The spacer chip as set forth in claim 16, wherein the respective bottom electrode terminals of said substrate spacer chip are defined as bottom metal bumps bonded to bottom end faces of the via plugs.

18. The spacer chip as set forth in claim 16, wherein the respective top electrode terminals of said substrate are defined as top metal bumps bonded to top end faces of the via plugs.

19. The spacer chip as set forth in claim 16, wherein the respective bottom electrode terminals of said substrate are defined as bottom end faces of the via plugs.

20. The spacer chip as set forth in claim 16, wherein the respective top electrode terminals of said substrate are defined as top end faces of the via plugs.

21. The spacer chip as set forth in claim 16, wherein said via plugs are arranged such that bottom end faces of said via plugs have a mirror image relationship with respect to the arrangement of the electrode terminals of said first semiconductor chip, and such that top end faces of said via plugs have a mirror image relationship with respect to the arrangement of the electrode terminals of said second semiconductor chip.

22. The spacer chip as set forth in claim 16, wherein said substrate has a bottom wiring layout pattern formed on the bottom surface thereof and electrically connected to said via plugs, and said bottom electrode terminals of said substrate are defined on said bottom wiring layout pattern such that there is a mirror image relationship between the arrangement of the electrode terminals of said substrate and the arrangement of the electrode terminals of said first semiconductor chip.

23. The spacer chip as set forth in claim 16, wherein said substrate has a top wiring layout pattern formed on the top surface thereof and electrically connected to said via plugs, and said top electrode terminals of said substrate are defined on said top wiring layout pattern such that there is a mirror image relationship between an arrangement of the top electrode terminals of said spacer chip and the arrangement of the electrode terminals of said second semiconductor chip.

24. The spacer chip as set forth in claim 16, wherein said substrate has a bottom wiring layout pattern formed on the bottom surface thereof and electrically connected to a part of said via plugs, and a part of the bottom electrode terminals of said substrate is defined on said bottom wiring layout pattern such that there is a mirror image relationship between an arrangement of the bottom electrode terminals of said substrate and the arrangement of the electrode terminals of said first semiconductor chip.

25. The spacer chip as set forth in claim 16, wherein said substrate has a top wiring layout pattern formed on the top surface thereof and electrically connected to a part of said via plugs, and a part of the top electrode terminals of said substrate is defined on said top wiring layout pattern such that there is a mirror image relationship between the arrangement of the top electrode terminals of said spacer chip and the arrangement of the electrode terminals of said second semiconductor chip.

26. The spacer chip as set forth in claim 16, wherein said substrate is composed of the same semiconductor material as said first and second semiconductor chips.
